(19) United States
(12) Patent Application Publication
(10) Pub. No.: US 2011/0240969 A1
(43) Pub. Date: Oct. 6, 2011

(54) Organic light-emitting device

(76) Inventors: Tae-Shick Kim, Yongin-City (KR); Kwan-Hee Lee, Yongin-City (KR); Dong-Heon Kim, Yongin-City (KR)

(21) Appl. No.: 13/064,583

(22) Filed: Apr. 1, 2011

(30) Foreign Application Priority Data
Apr. 2, 2010 (KR) 10-2010-0030502

(51) Int. Cl. H01L 51/54

(52) U.S. Cl. 257/40; 257/E51.049; 257/E51.05; 257/E51.051

(57) ABSTRACT

An organic light-emitting device including a substrate; a first electrode disposed on the substrate; a second electrode; an organic layer disposed between the first electrode and the second electrode, the organic layer including an emission layer and an electron transport layer, the electron transport layer including an anthracene-based compound and a quinolate-based compound; and at least one first layer disposed between the first electrode and the emission layer, the at least one first layer including a cyano group-containing compound.

### BACKGROUND

1. Field

Embodiments relate to an organic light-emitting device.

2. Description of the Related Art

Organic light-emitting devices (OLEDs), which are self-emitting devices, have advantages such as a wide viewing angle, excellent contrast, quick response, high brightness, and excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. In this regard, the HTL, the EML, and the ETL are organic thin films formed of organic compounds.

An operating principle of an OLED having the above-described structure is as follows. When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

An OLED has not had fully satisfactory characteristics in terms of luminance, efficiency, driving stability, lifetime, and the like, and thus there is an urgent need for development of various technologies. To address these problems, it is necessary to develop an OLED that has high luminance, drives at a low voltage, and has excellent efficiency and performance.

### SUMMARY

It is a feature of an embodiment to provide an organic light-emitting device (OLED) having excellent driving voltage characteristics, luminous efficiency characteristics, and power efficiency characteristics.

At least one of the above and other features and advantages may be realized by providing an organic light-emitting device, including a substrate; a first electrode disposed on the substrate; a second electrode; an organic layer disposed between the first electrode and the second electrode, the organic layer including an emission layer and an electron transport layer, the electron transport layer including an anthracene-based compound and a quinolate-based compound; and at least one first layer disposed between the first electrode and the emission layer, the at least one first layer including a cyano group-containing compound.

The cyano group-containing compound may include at least one compound represented by Formulae 1 through 20.

In Formulae 1 through 20,

X₁ through X₄ may each independently be compounds represented by Formulae 30A through 30D;

Y₁ through Y₈ may each independently be N or C(R₁₀₃);

Z₁ through Z₄ may each independently be C or N;

A₁ and A₂ may each independently be —O—, —S—, —N(R₁₀₄), or —C(R₁₀₅)(R₁₀₆)—;

Q₁₀₁ and Q₁₀₂ may each independently be a C₂-C₁₀ alkylene group; a C₂-C₁₀ alkenylene group; or a substituted C₂-C₁₀ alkylene group or a substituted C₂-C₁₀ alkenylene group which have at least one substituent that is a halogen atom, a cyano group, a hydroxyl group, a C₁-C₁₀ alkyl group, or a C₁-C₁₀ alkoxy group;

T₁ and T₂ may each independently be a C₅-C₃₀ aromatic ring system; a C₂-C₃₀ heteroaromatic ring system; or a substituted C₅-C₃₀ aromatic ring system or a substituted C₂-C₃₀ heteroaromatic ring system which have at least one substituent that is a halogen atom, a cyano group, a hydroxyl group, a C₁-C₁₀ alkyl group, or a C₁-C₁₀ alkoxy group;

p may be an integer from 1 to 10;

q may be an integer from 0 to 10;

R₁₀₁ through R₁₀₆ may each independently be hydrogen; a halogen atom; a cyano group; a hydroxyl group; a C₁-C₁₀ alkyl group; a C₁-C₁₀ alkoxy group; a substituted C₁-C₁₀alkyl group or a substituted C₁-C₁₀ alkoxy group which have at least one substituent that is a halogen atom, a cyano group, a hydroxyl group, a C₅-C₁₄ aryl group, or a C₂-C₁₄ heteroaryl group;

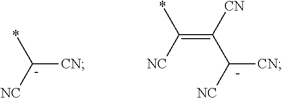

or —N(R₁₀₇)(R₁₀₈), wherein R₁₀₇ and R₁₀₈ may each independently be hydrogen, a C₁-C₁₀ alkyl group, a phenyl group, and a biphenyl group;

L₁₀₁ may be a C₅-C₁₄ arylene group; a C₅-C₁₄ heteroarylene group; or a substituted C₂-C₁₀ alkenylene group, a substituted C₅-C₁₄ arylene group, or a substituted C₅-C₁₄ heteroarylene group which have at least one substituent that is a halogen atom, a cyano group, a hydroxyl group, a C₁-C₁₀ alkyl group, or a C₁-C₁₀ alkoxy group.

X₁ through X₄ may each independently be the compound represented by Formula 30A or the compound represented by Formula 30D.

R₁₀₃ may be hydrogen; a halogen atom; a cyano group; a C₁-C₁₀ alkyl group; a C₁-C₁₀ alkoxy group; a substituted C₁-C₁₀ alkyl group or a substituted C₁-C₁₀ alkoxy group which have at least one substituent that is a halogen atom, a cyano group, a phenyl group, a naphthyl group, an anthryl group, a pyridinyl group, a thiophenyl group, or a benzothiophenyl group; or —N(R₁₀₇)(R₁₀₈), wherein R₁₀₇ and R₁₀₈ may each independently be hydrogen, a C₁-C₁₀ alkyl group, a phenyl group, or a biphenyl group.

T₁ and T₂ may each independently be benzene; naphthalene; anthracene; thiophene; thiadiazole; oxadiazole; or a substituted benzene, a substituted naphthalene, a substituted anthracene, a substituted thiophene, a substituted thiadiazole, or a substituted oxadiazole which have at least one substituent that is a halogen atom, a cyano group, a C₁-C₁₀ alkyl group, or a C₁-C₁₀ alkoxy group.

L₁₀₁ may be a thiophenylene group; a benzothiophenylene group; or a substituted thiophenylene group or a substituted benzothiophenylene group which have at least one substituent that is a halogen atom, a cyano group, or a C₁-C₁₀ alkyl group.

The cyano group-containing compound may include at least one compound represented by Formulae 1A through 20B.

In Formulae 1A through 20B, R₁₀₃ and R₁₀₉ may each independently be a hydrogen atom, —F, a cyano group, a methyl group, an ethyl group, a propyl group, a ethenyl group, a methoxy group, an ethoxy group, or a propoxy group.

The first layer may further include a hole transporting compound.

The hole transporting compound may include a compound represented by Formula 41 or 42.

In Formulae 41 and 42,

R₁₀ may be represented by —(Ar₁)ₙ—Ar₂;

R₁₆ may be represented by —(Ar₁₁)ₘ—A₁₂;

Ar₁, Ar₁₁, L₁, and L₁₁ may each independently be a substituted or unsubstituted C₁-C₃₀ alkylene group, a substituted or unsubstituted C₂-C₃₀ alkenylene group, a substituted or unsubstituted C₅-C₃₀ arylene group, a substituted or unsubstituted C₄-C₃₀ heteroarylene group, or —N(Q₁)-;

n, m, a, and b may each independently be an integer from 0 to 10;

R₁ through R₃, R₁₁ through R_{15,} R₁₇, R₁₈, R₂₁ through R₂₉, Ar₂, Ar₁₂, and Q₁ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₅-C₃₀ aryl group, a C₄-C₃₀ heteroaryl group, or —N(Q₂)(Q₃);

Q₂ and Q₃ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₅-C₃₀ aryl group, or a substituted or unsubstituted C₄-C₃₀ heteroaryl group; and

n groups of Ar₁ in —(Ar₁)ₙ— may be identical to or different from each other, m groups of Ar₁₁ in —(Ar₁₁)ₘ— may be identical to or different from each other, a groups of L₁ in -(L₁)ₐ- may be identical to or different from each other, and b groups of L₁₁ in -(L₁₁)_{b}- may be identical to or different from each other.

A₁ and Ar₁₁ may each independently be a C₁-C₁₀ alkylene group; a phenylene group; a naphthylene group; an anthrylene group; a fluorenylene group; a carbazolylene group; a pyrazolylene group; a pyridinylene group; a triazinylene group; —N(Q₁)-; or a substituted C₁-C₁₀ alkylene group, a substituted phenylene group, a substituted naphthylene group, a substituted anthrylene group, a substituted fluorenylene group, a substituted carbazolylene group, a substituted pyrazolylene group, a substituted pyridinylene group, or a substituted triazinylene group which have at least one substituent that is halogen atom, a cyano group, a hydroxyl group, a C₁-C₁₀ alkyl group, a C₁-C₁₀ alkoxy group, a phenyl group, a naphthyl group, or an anthryl group; and

Q₁ may be hydrogen; a C₁-C₁₀ alkyl group; a phenyl group; a naphthyl group; a carbazolyl group; a fluorenyl group; or a substituted C₁-C₁₀ alkyl group, a substituted C₁-C₁₀ alkoxy group, a substituted phenyl group, a substituted naphthyl group, a substituted carbazolyl group, or a substituted fluorenyl group which have at least one substituent that is a halogen atom, a cyano group, a hydroxyl group, a C₁-C₁₀ alkyl group, a C₁-C₁₀ alkoxy group, a phenyl group, a naphthyl group, or an anthryl group.

Ar₂ and Ar₁₂ may each independently be hydrogen; a C₁-C₁₀ alkyl group; a phenyl group; a naphthyl group; a carbazolyl group; a fluorenyl group; a pyrenyl group; a substituted C₁-C₁₀ alkyl group, a substituted C₁-C₁₀ alkoxy group, a substituted phenyl group, a substituted naphthyl group, a substituted carbazolyl group, a substituted fluorenyl group, or a substituted pyrenyl group which have at least one substituent that is a halogen atom, a cyano group, a hydroxyl group, a C₁-C₁₀ alkyl group, a C₁-C₁₀ alkoxy group, a phenyl group, a naphthyl group, or an anthryl group; or —N(Q₂)(Q₃), wherein Q₂ and Q₃ may each independently be hydrogen, a methyl group, an ethyl group, a phenyl group, a methylphenyl group, a biphenyl group, a naphthyl group, or a methylnaphthyl group.

The amount of the cyano group-containing compound in the first layer may be about 0.1 to about 20 parts by weight, based on 100 parts by weight of the first layer.

The first layer may have a thickness of about 10 Å to about 2,100 Å.

A distance between the first layer and the emission layer may be 50 Å or greater.

The organic light-emitting device may further include, between the first layer and the emission layer, at least one of a hole injection layer and a hole transport layer.

The anthracene-based compound may include at least one of a compound represented by Formula 101 and a compound represented by Formula 102, and the quinolate-based compound may include at least one of lithium quinolate (LiQ) and LiF.

In Formulae 101 and 102,

R*₁ through R*₆ may each independently be a hydrogen atom, a halogen atom, a hydroxy group, a cyano group, a substituted or unsubstituted C₁-C₃₀ alkyl group, a substituted or unsubstituted C₁-C₃₀ alkoxy group, a substituted or unsubstituted C₁-C₃₀ acyl group, a substituted or unsubstituted C₂-C₃₀ alkenyl group, a substituted or unsubstituted C₂-C₃₀ alkynyl group, a substituted or unsubstituted C₆-C₃₀ aryl group, or a substituted or unsubstituted C₃-C₃₀ heteroaryl group, wherein at least two adjacent groups of R*₁ through R*₆ are linked to form a saturated or unsaturated ring;

L*₁ may be a single bond, a substituted or unsubstituted C₁-C₃₀ alkylene group, a substituted or unsubstituted C₆-C₃₀ arylene group, or a substituted or unsubstituted C₃-C₃₀ hetero arylene group;

Q*₁ through Q*₉ may each independently be a hydrogen atom, a substituted or unsubstituted C₆-C₃₀ aryl group, or a substituted or unsubstituted C₃-C₃₀ heteroaryl group; and

a* may be an integer from 1 to 10.

The anthracene-based compound may include at least one of a compound represented by Formula 103 and a compound represented by Formula 104, and the quinolate-based compound may include at least one of lithium quinolate (LiQ) and LiF.

The amount of the anthracene-based compound may be about 50 to about 150 parts by weight, based on 100 parts by weight of the quinolate-based compound.

The emission layer may include a blue dopant and a blue host.

The emission layer may include a blue dopant represented by Formula 201 and a blue host represented by Formula 202.

In Formulae 201 and 202,

L₂₁ may be a substituted or unsubstituted C₁-C₃₀ alkylene group, a substituted or unsubstituted C₂-C₃₀ alkenylene group, a substituted or unsubstituted C₅-C₃₀ arylene group, or a substituted or unsubstituted C₄-C₃₀ heteroarylene group;

c may be an integer from 1 to 20;

R₃₁ through R₃₄ may each independently be a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₅-C₃₀ aryl group, or a substituted or unsubstituted C₄-C₃₀ heteroaryl group.

c groups of L₂₁ in -(L₂₁)_{c}- may be identical to or different from each other;

Ar₅₁, A₅₂, Ar₅₃, and Ar₅₄ may each independently be a phenylene group, a naphthylene group, an anthrylene group, or a phenyl-substituted anthrylene group,

R₅₁ through R₅₆ may each independently be a hydrogen atom, a methyl group, an ethyl group, a propyl group, a butyl group, a phenyl group, a naphthyl group, an anthryl group, a pyrenyl group, a carbazolyl group, or —N(Q₂)(Q₃), wherein Q₂ and Q₃ may each independently be a methyl group, a phenyl group, a naphthyl group, or an anthryl group; and

d, e, f, and g may each independently be an integer from 0 to 10.

### BRIEF DESCRIPTION OF THE DRAWING

The above and other features and advantages will become more apparent to those of skill in the art by describing in detail example embodiments with reference to the attached drawing, in which:

FIG. 1 illustrates a cross-sectional view of a structure of an organic light-emitting device (OLED) according to an embodiment.

### DETAILED DESCRIPTION

Korean Patent Application No. 10-2010-0030502, filed on Apr. 2, 2010, in the Korean Intellectual Property Office, and entitled: “Organic Light-Emitting Device,” is incorporated by reference herein in its entirety.

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figure, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

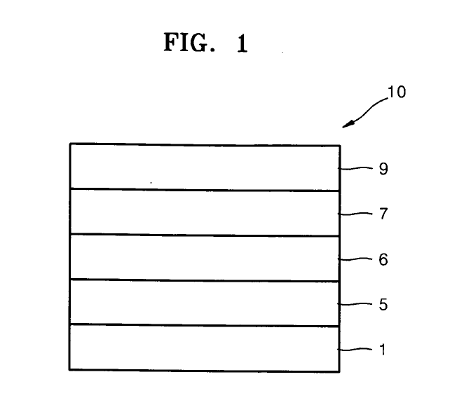

FIG. 1 illustrates a schematic cross-sectional view of a structure of an organic light-emitting device (OLED) 10 according to an embodiment. Referring to FIG. 1, the OLED 10 according to an embodiment may include a substrate 1, a first electrode 5, a first layer 6, an organic layer 7, and a second electrode 9 sequentially stacked in the stated order. The first layer 6 may include a cyano group-containing compound. The organic layer 7 may include an emission layer (EML) and an electron transport layer (ETL).

The substrate 1 may be a suitable substrate that is used in conventional organic light-emitting devices. The substrate 1 may be, e.g., a glass substrate or a transparent plastic substrate providing one or more of mechanical strength, thermal stability, transparency, surface smoothness, ease of handling, and water resistance.

The first electrode 5 may constitute an anode or a cathode. Examples of the first electrode material include materials, such as indium tin oxide (ITO), indium zinc oxide (IZO), tin oxide (SnO₂), zinc oxide (ZnO), aluminum (Al), silver (Ag), and magnesium (Mg), which have excellent conductivity. The first electrode material may form a transparent or reflective electrode.

The first layer 6 may include a cyano group-containing compound and may be disposed on the first electrode 5. The first layer 6 may include at least one layer. The cyano group-containing compound included in the first layer 6 has two one-electron reduced forms, and may have an extended π-electron system capable of generating stable radicals (this can be identified by, e.g., cyclic voltammetry). The first layer 6 may lower a barrier of hole injection from the first electrode 5 into the organic layer 7. Thus, the first layer 6 may facilitate the injection of holes into the organic layer 7 from the first electrode 5. Thus, the OLED 10 may have excellent driving voltage characteristics and power efficiency characteristics.

The cyano group-containing compound included in the first layer 6 may be one of the compounds represented by Formulae 1 through 20 below.

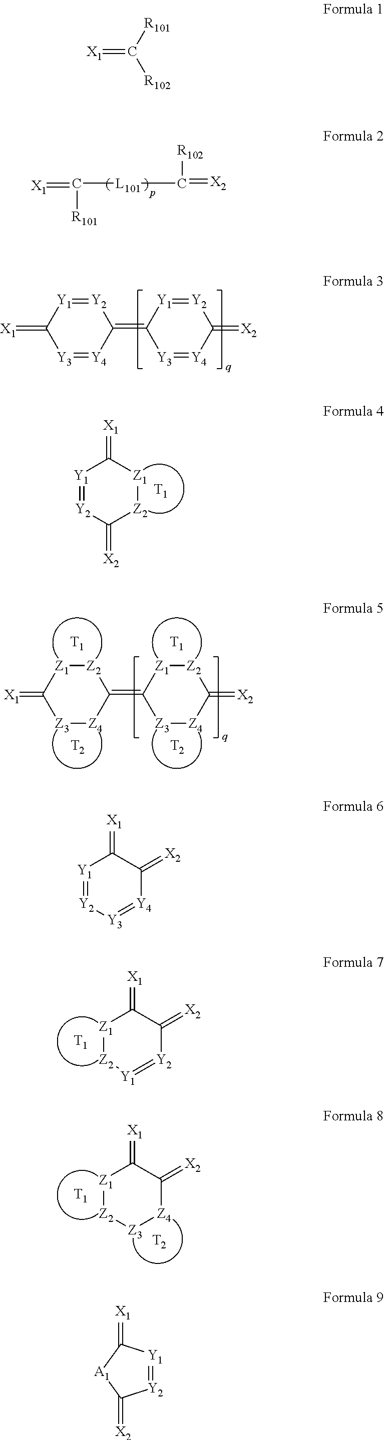

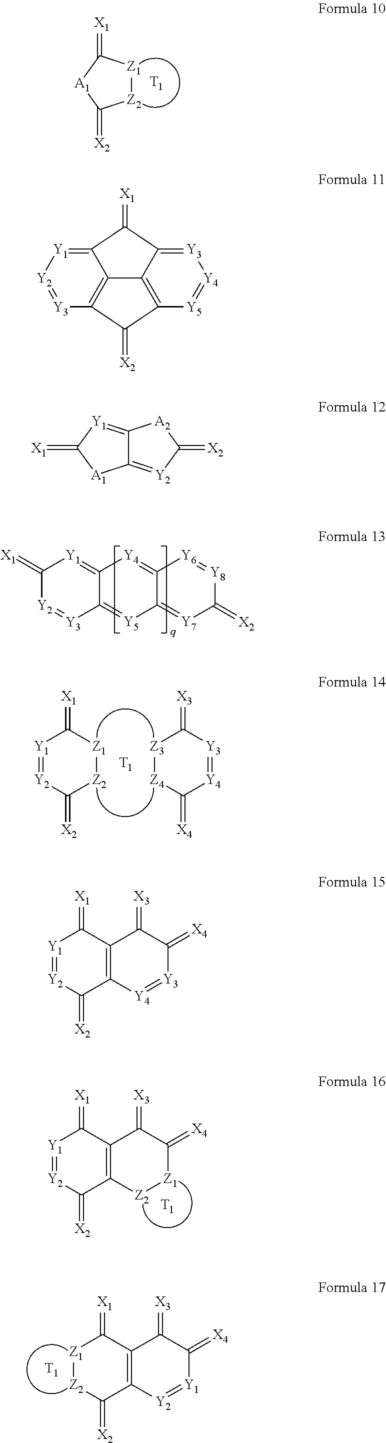

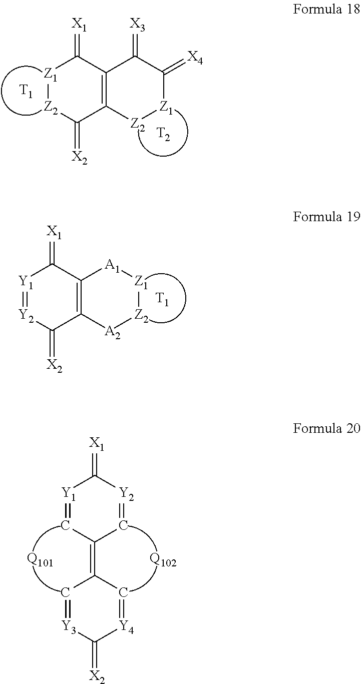

In Formulae 1 through 20, X₁ through X₄ may each independently be compounds represented by Formulae 30A through 30D below; Y₁ through Y₈ may each independently be N or C(R₁₀₃); Z₁ through Z₄ may each independently be C or N; A₁ and A₂ may each independently be —O—, —S—, —N(R₁₀₄) or —C(R₁₀₅)(R₁₀₆)—; Q₁₀₁ and Q₁₀₂ may each independently be a C₂-C₁₀ alkylene group, a C₂-C₁₀ alkenylene group, or a substituted C₂-C₁₀ alkylene group or a substituted C₂-C₁₀ alkenylene group which have at least one substituent that is a halogen atom, a cyano group, a hydroxyl group, a C₁-C₁₀ alkyl group or a C₁-C₁₀ alkoxy group; T₁ and T₂ may each independently be a C₅-C₃₀ aromatic ring system, a C₂-C₃₀ heteroaromatic ring system, or a substituted C₅-C₃₀ aromatic ring system or a substituted C₂-C₃₀ heteroaromatic ring system which have at least one substituent that is a halogen atom, a cyano group, a hydroxyl group, a C₁-C₁₀ alkyl group or a C₁-C₁₀ alkoxy group; p may be an integer from 1 to 10; q may be an integer from 0 to 10; R₁₀₁ through R₁₀₆ may each independently be hydrogen, a halogen atom, a cyano group, a hydroxyl group, a C₁-C₁₀ alkyl group, a C₁-C₁₀ alkoxy group, a substituted C₁-C₁₀ alkyl group or a substituted C₁-C₁₀ alkoxy group which have at least one substituent that is a halogen atom, a cyano group, a hydroxyl group, a C₅-C₁₄ aryl group, or a C₂-C₁₄ heteroaryl group,

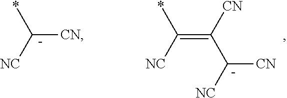

or —N(R₁₀₇)(R₁₀₈), wherein R₁₀₇ and R₁₀₈ are each independently hydrogen, a C₁-C₁₀ alkyl group, a phenyl group, or a biphenyl group; and L₁₀₁ may be a C₅-C₁₄ arylene group, a C₅-C₁₄ heteroarylene group, or a substituted C₂-C₁₀ alkenylene group, a substituted C₅-C₁₄ arylene group or a substituted C₅-C₁₄ heteroarylene group which have at least one substituent that is a halogen atom, a cyano group, a hydroxyl group, a C₁-C₁₀ alkyl group, or a C₁-C₁₀ alkoxy group.

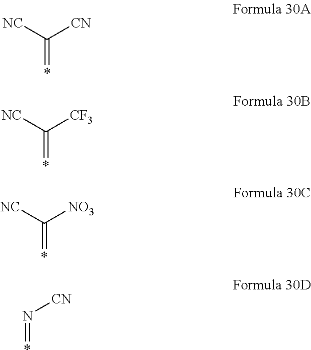

For example, in Formula 1 through 20, X₁ through X₄ may each independently be a compound represented by Formula 30A or a compound represented by Formula 30D.

For example, R₁₀₃ in C(R₁₀₃) for Y₁ through Y₈ in Formulae 1 through 20 may be hydrogen; a halogen atom; a cyano group; a C₁-C₁₀ alkyl group; a C₁-C₁₀ alkoxy group; a substituted C₁-C₁₀ alkyl group or a substituted C₁-C₁₀ alkoxy group which have at least one substituent that is a halogen atom, a cyano group, a phenyl group, a naphthyl group, an anthryl group, a pyridinyl group, a thiophenyl group, or a benzothiophenyl group; or —N(R₁₀₇)(R₁₀₈), wherein R₁₀₇ and R₁₀₈ may each independently be hydrogen, a C₁-C₁₀ alkyl group, a phenyl group, or a biphenyl group.

In particular, R₁₀₃ may be hydrogen, —F, a cyano group, a methyl group, an ethyl group, a propyl group, an ethenyl group, a methoxy group, an ethoxy group, a propoxy group, a phenyl-substituted methyl group, a phenyl-substituted propyl group, or an —N(biphenyl group)(biphenyl group), but is not limited thereto.

In Formulae 1 and 2, R₁₀₁ and R₁₀₂ may each independently be a cyano group,

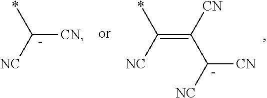

but are not limited thereto.

In Formulae 1 through 20, A₁ and A₂ may be —S—, but are not limited thereto.

In Formula 20, Q₁₀₁ and Q₁₀₂ may each independently be an ethylene group, a propylene group, an ethenylene group, a propylene group, or a substituted ethylene group, a substituted propylene group, a substituted ethenylene group, or a substituted propylene group which have at least one substituent that is a halogen atom, a cyano group, or a hydroxyl group. In particular, Q₁₀₁ and Q₁₀₂ may each independently be an ethylene group, an ethenylene group, or a substituted ethylene group or a substituted ethenylene group which have at least one substituent that is —F or a cyano group, but are not limited thereto.

In Formulae 1 through 20, T₁ and T₂ may each independently be a C₅-C₃₀ aromatic ring system including elements Z₁ and Z₂, or Z₃ and Z₄; a C₂-C₃₀ heteroaromatic ring system; a substituted C₅-C₃₀ aromatic ring system having at least one substituent that is a halogen atom, a cyano group, a hydroxyl group, a C₁-C₁₀ alkyl group, or a C₁-C₁₀ alkoxy group; or a substituted C₅-C₃₀ heteroaromatic ring system having at least one substituent that is a halogen atom, a cyano group, a hydroxyl group, a C₁-C₁₀ alkyl group, or a C₁-C₁₀ alkoxy group. In an implementation, T₁ and T₂ may each independently be a C₆-C₃₀ aromatic ring system including elements Z₁ and Z₂, or Z₃ and Z₄; a C₂-C₃₀ heteroaromatic ring system; a substituted C₆-C₃₀ aromatic ring system having at least one substituent that is a halogen atom, a cyano group, a hydroxyl group, a C₁-C₁₀ alkyl group, or a C₁-C₁₀ alkoxy group; or a substituted C₅-C₃₀ heteroaromatic ring system having at least one substituent that is a halogen atom, a cyano group, a hydroxyl group, a C₁-C₁₀ alkyl group, or a C₁-C₁₀ alkoxy group. As identified from Formulae 1 through 20, T₁ and T₂ are fused to the backbones of Formulae 1 through 20.

The C₅-C₃₀ aromatic ring system refers to a C₅-C₃₀ carbocyclic aromatic system including at least one aromatic ring. In this regard, the term “system” used herein indicates that the C₅-C₃₀ aromatic ring system may include a polycyclic structure. When the C₅-C₃₀ aromatic ring system includes 2 or more aromatic rings, the 2 or more aromatic rings may be fused together. The C₂-C₃₀ heteroaromatic ring system refers to a C₂-C₃₀ carbocyclic aromatic system including at least one heteroaromatic ring, wherein the at least one heteroaromatic ring includes at least one heteroatom that is nitrogen (N), oxygen (O), phosphorous (P) or sulfur (S), and has carbon (C) as the other ring atoms. When the C₂-C₃₀ heteroaromatic ring system further includes at least one of an aromatic ring group and a heteroaromatic ring, two or more (hetero)aromatic rings may be fused together.

Examples of the C₅-C₃₀ aromatic ring system include benzene, pentalene, indene, naphthalene, azulene, heptalene, indacene, acenaphthylene, fluorene, phenalene, phenanthrene, anthracene, fluoranthene, triphenylene, pyrene, chrysene, naphthacene, picene, perylene, pentaphene, and hexacene, but are not limited thereto.

Examples of the C₅-C₃₀ heteroaromatic ring system include pyrrole, pyrazole, imidazole, imidazoline, pyridine, pyrazine, pyrimidine, indole, purine, quinoline, phthalazine, indolizine, naphthyridine, quinazoline, cinnoline, indazole, carbazole, phenazine, phenanthridine, pyran, chromene, benzofuran, thiophene, benzothiophene, isothiazole, isoxazole, thiadiazole, and oxadiazole, but are not limited thereto.

For example, in Formulae 1 through 20, T₁ and T₂ may each independently be benzene; naphthalene; anthracene; thiophene; thiadiazole; oxadiazole; or a substituted benzene, a substituted naphthalene, a substituted anthracene, a substituted thiophene, a substituted thiadiazole, or a substituted oxadiazole which have at least one substituent that is a halogen atom, a cyano group, a C₁-C₁₀ alkyl group, or a C₁-C₁₀ alkoxy group.

In Formulae 1 through 20, p may be 1, but is not limited thereto. In addition, q may be 0, 1, or 2, but is not limited thereto. For example, when q in Formula 3 is 0, the compound represented by Formula 3 may be a compound represented by Formula 3A, which will be described below.

In Formula 2, L₁₀₁ may be a C₅-C₁₄ arylene group; a C₅-C₁₄ heteroarylene group; a substituted C₅-C₁₄ arylene group having at least one substituent that is a halogen atom, a cyano group, a hydroxyl group, a C₁-C₁₀ alkyl group or a C₁-C₁₀ alkoxy group; or a substituted C₅-C₁₄ heteroarylene group having at least one substituent that is a C₂-C₁₀ alkenylene group, a halogen atom, a cyano group, a hydroxyl group, a C₁-C₁₀ alkyl group, or a C₁-C₁₀ alkoxy group. In an implementation, L₁₀₁ may be a C₆-C₁₄ arylene group; a C₅-C₁₄ heteroarylene group; a substituted C₆-C₁₄ arylene group having at least one substituent that is a halogen atom, a cyano group, a hydroxyl group, a C₁-C₁₀ alkyl group or a C₁-C₁₀ alkoxy group; or a substituted C₅-C₁₄ heteroarylene group having at least one substituent that is a C₂-C₁₀ alkenylene group, a halogen atom, a cyano group, a hydroxyl group, a C₁-C₁₀ alkyl group, or a C₁-C₁₀ alkoxy group. For example, L₁₀₁ may be a thiophenylene group; a benzothiophenylene group; or a substituted thiophenylene group or a substituted benzothiophenylene group which have at least one substituent that is a halogen atom, a cyano group, or a C₁-C₁₀ alkyl group.

One or more of the compounds represented by Formulae 1A through 20B, below, may be used for the cyano group-containing compound included in the first layer 6 of the OLED 10, but the cyano group-compound is not limited to Formulae 1A through 20B:

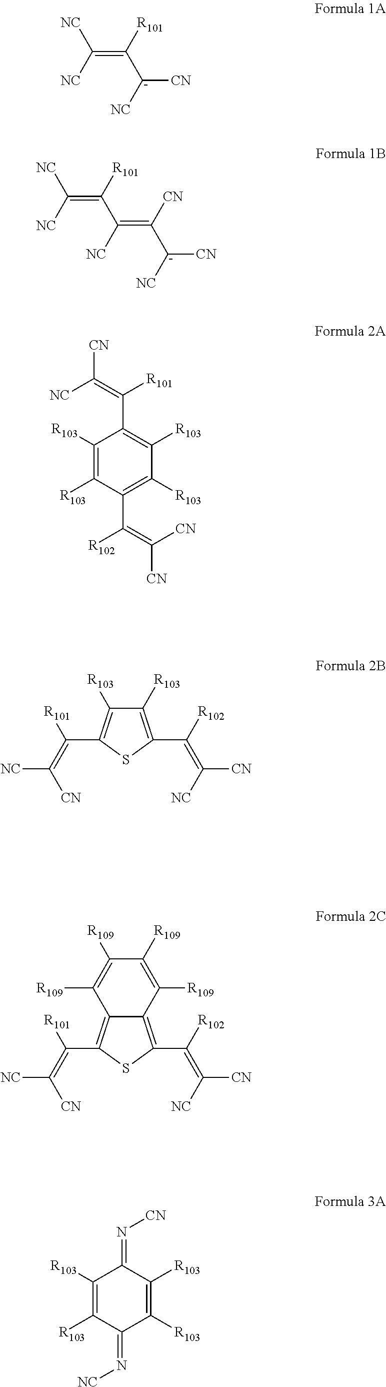

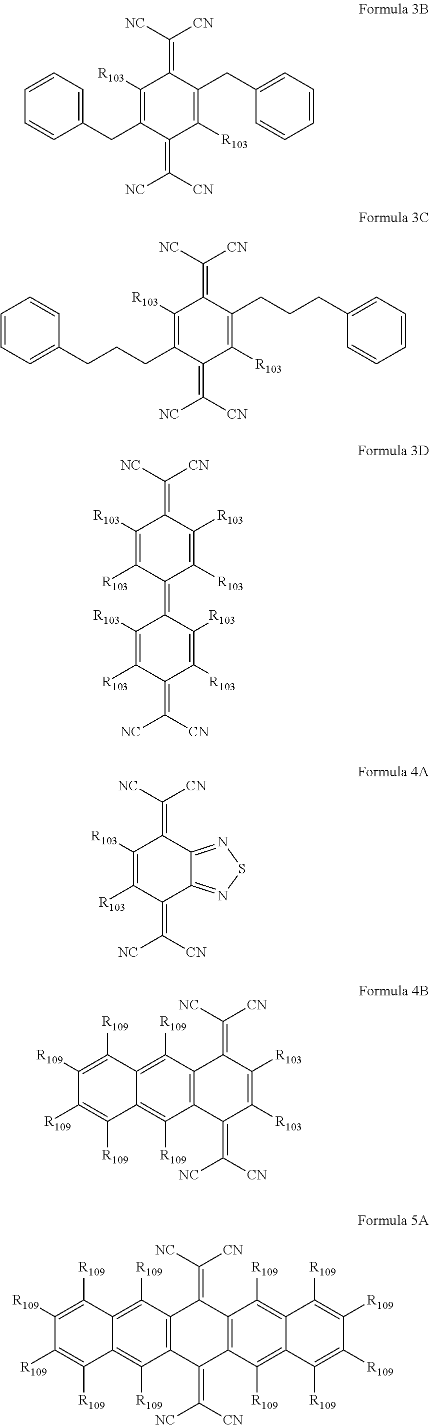

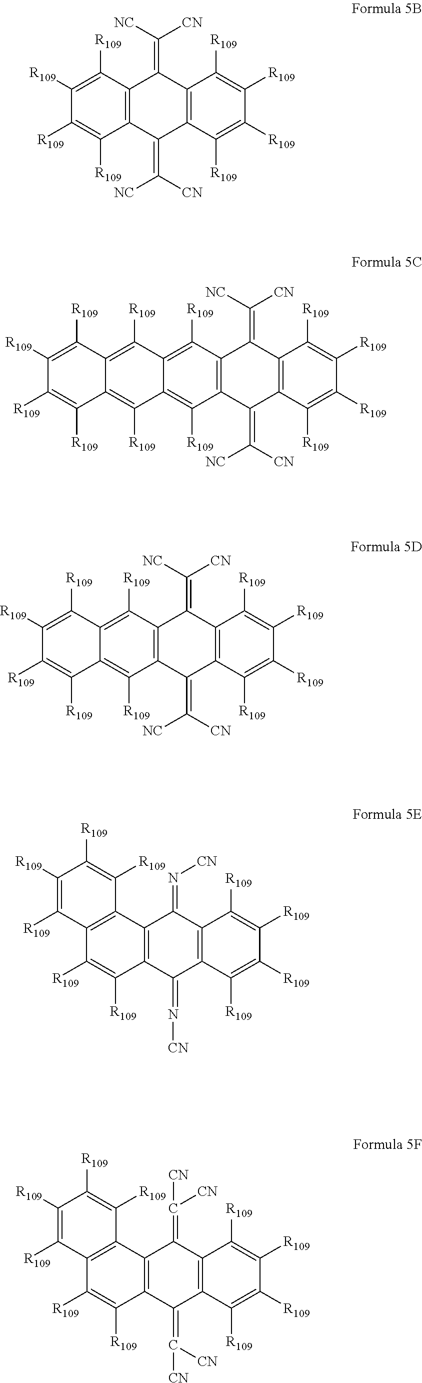

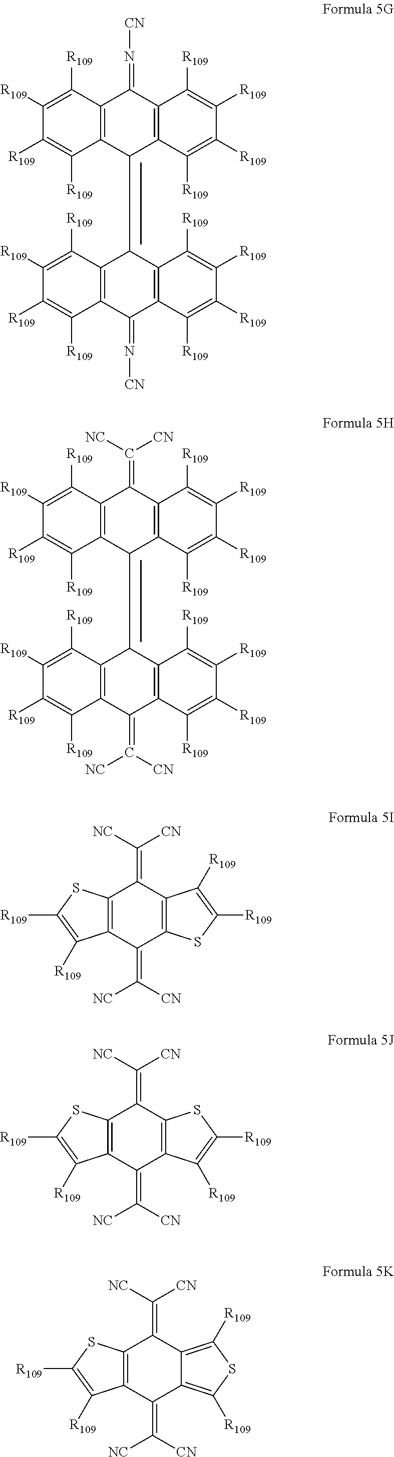

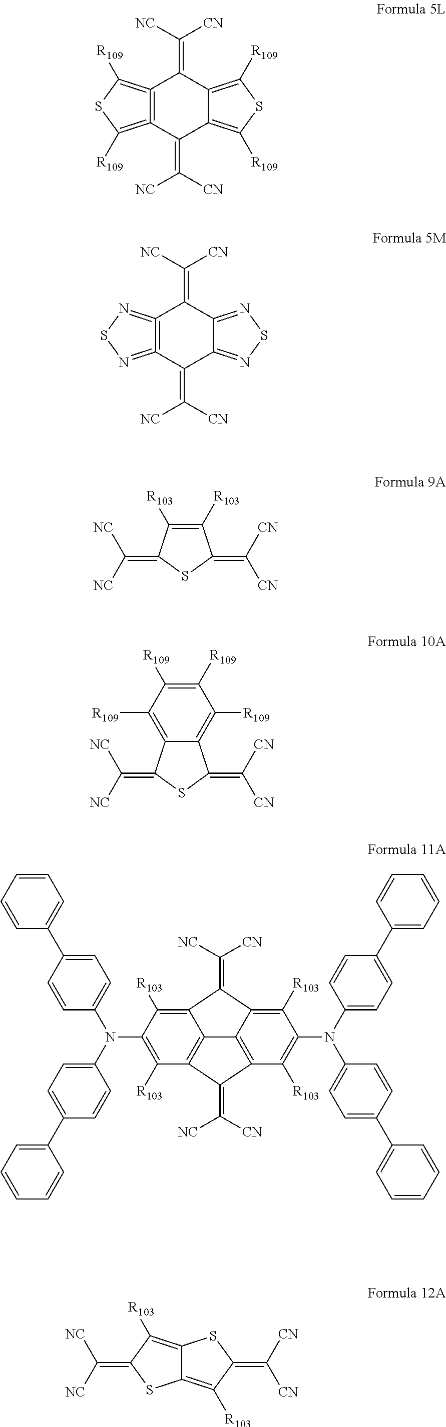

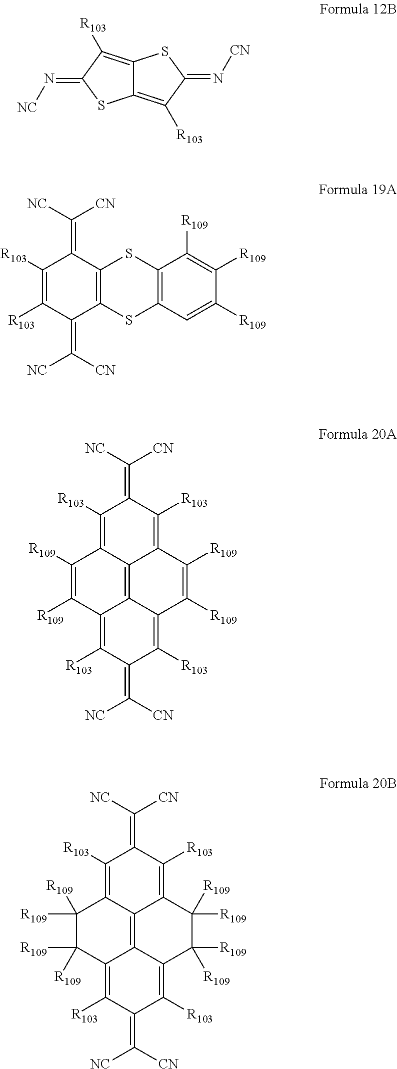

In Formulae 1A through 20B, R₁₀₃ and R₁₀₉ may each independently be a hydrogen atom, —F, a cyano group, a methyl group, an ethyl group, a propyl group, a methoxy group, an ethoxy group, or a propoxy group.

For example, the compound represented by Formula 20A or 20B may be the cyano group-containing compound included in the first layer 6 of the OLED 10. In Formulae 20A and 20B, R₁₀₃ and R₁₀₉ may both be —F.

The cyano group-containing compound included in the first layer 6 may improve the hole injecting ability of the first electrode 5. Thus, the OLED 10 may have a reduced driving voltage and higher emission and power efficiencies.

The first layer 6 may include a hole transporting compound. In an embodiment, the first layer 6 may include the hole transporting compound in addition to the cyano group-containing compound described above. The cyano group-containing compound may form a charge transfer complex with the hole transporting compound, so that the concentration of free carriers in the first layer 6 may be increased. Thus, the cyano group-containing compound may contribute to a reduction in interfacial resistance between the first electrode 5 and the organic layer 7.

One or more of the compounds represented by Formulae 41 and 42, below, may be used for the hole transporting compound, but the hole transporting compound is not limited thereto:

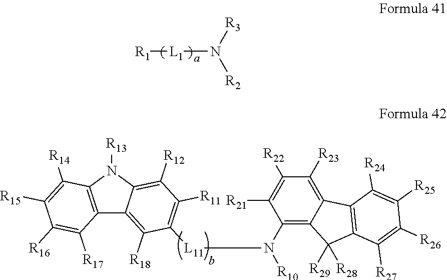

In Formulae 41 and 42, R₁₀ may be represented by —(Ar₁)ₙ—Ar₂; R₁₆ may be represented by —(Ar₁₁)ₘ—Ar₁₂; Ar₁, Ar₁₁, L₁ and L₁₁ may each independently be a substituted or unsubstituted C₁-C₃₀ alkylene group, a substituted or unsubstituted C₂-C₃₀ alkenylene group, a substituted or unsubstituted C₅-C₃₀ arylene group, a substituted or unsubstituted C₄-C₃₀ heteroarylene group, or a group represented by —N(Q₁)-; n, m, a, and b may each independently be an integer from 0 to 10; R₁ through R₃, R₁₁ through R₁₅, R₁₇, R₁₈, R₂₁ through R₂₉, Ar₂, Ar₁₂, and Q₁ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₅-C₃₀ aryl group, a substituted or unsubstituted C₄-C₃₀ heteroaryl group, or a group represented by —N(Q₂)(Q₃); and Q₂ and Q₃ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₅-C₃₀ aryl group, or a substituted or unsubstituted C₄-C₃₀ heteroaryl group, wherein n groups of Ar₁ in —(Ar₁)ₙ— may be identical to or different from each other, m groups of Ar₁₁ in —(Ar₁₁)ₘ— may be identical to or different from each other, a groups of L₁ in -(L₁)ₐ- may be identical to or different from each other, and b groups of L₁₁ in -(L₁₁)_{b}- may be identical to or different from each other. In an implementation, L₁ and L₁₁ may each independently be a substituted or unsubstituted C₁-C₃₀ alkylene group, a substituted or unsubstituted C₂-C₃₀ alkenylene group, a substituted or unsubstituted C₆-C₃₀ arylene group, a substituted or unsubstituted C₄-C₃₀ heteroarylene group, or a group represented by —N(Q₁)-; R₁ through R₃, R₁₁ through R₁₅, R₁₇, R₁₈, R₂₁ through R₂₉, Ar₂, Ar₁₂ and Q₁ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₆-C₃₀ aryl group, a substituted or unsubstituted C₄-C₃₀ heteroaryl group, or a group represented by —N(Q₂)(Q₃); and Q₂ and Q₃ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀alkoxy group, a substituted or unsubstituted C₁-C₃₀ alkylthiol group, a substituted or unsubstituted C₆-C₃₀ aryl group, or a substituted or unsubstituted C₄-C₃₀ heteroaryl group.

Examples of Ar₁ in the formula —(Ar₁)ₙ—Ar₂— for R₁₀ and Ar₁₁ in the formula —(Ar₁₁)ₘ—Ar₁₂— for R₁₆ may each independently be a substituted or unsubstituted C₁-C₁₀ alkylene group, a substituted or unsubstituted C₂-C₁₀ alkenylene group, a substituted or unsubstituted phenylene group, a substituted or unsubstituted pentalenylene group, a substituted or unsubstituted indenylene group, a substituted or unsubstituted naphthylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluorenylene group, a substituted or unsubstituted phenalenylene group, a substituted or unsubstituted phenanthrenylene group, a substituted or unsubstituted anthracenylene group, a substituted or unsubstituted fluoranthenylene group, a substituted or unsubstituted triphenylenylene group, a substituted or unsubstituted pyrenylenylene group, a substituted or unsubstituted chrysenylene group, a substituted or unsubstituted perylenylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted imidazopyridinylene group, a substituted or unsubstituted imidazopyrimidinylene group, a substituted or unsubstituted pyridinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted carbazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, a substituted or unsubstituted triazinylene group, or a group represented by —N(Q₁)-, but are limited thereto. In this regard, Q₁ may be hydrogen, a halogen atom, a hydroxyl group, a cyano group, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted C₁-C₁₀ alkylthiol group, a substituted or unsubstituted C₅-C₁₄ aryl group, a substituted or unsubstituted C₄-C₁₄ heteroaryl group, or —N(Q₂)(Q₃), but is not limited thereto. In an implementation, Q₁ may be hydrogen, a halogen atom, a hydroxyl group, a cyano group, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted C₁-C₁₀ alkylthiol group, a substituted or unsubstituted C₆-C₁₄ aryl group, a substituted or unsubstituted C₄-C₁₄ heteroaryl group, or —N(Q₂)(Q₃), but is not limited thereto.

For example, Ar₁ and Ar₁₁ may each independently be a C₁-C₁₀ alkylene group; a phenylene group; a naphthylene group; an anthrylene group; a fluorenylene group; a carbazolylene group; a pyrazolylene group; a pyridinylene group; a triazinylene group; —N(Q₁)-; or a substituted C₁-C₁₀ alkylene group, a substituted phenylene group, a substituted naphthylene group, a substituted anthrylene group, a substituted fluorenylene group, a substituted carbazolylene group, a substituted pyrazolylene group, a substituted pyridinylene group, or a substituted triazinylene group which have at least one substituent that is a halogen atom, a cyano group, a hydroxyl group, a C₁-C₁₀ alkyl group, a C₁-C₁₀ alkoxy group, a phenyl group, a naphthyl group, or an anthryl group. In this regard, Q₁ may be hydrogen; a C₁-C₁₀ alkyl group; a phenyl group; a naphthyl group; a carbazolyl group; a fluorenyl group; a pyrenyl group; a substituted C₁-C₁₀ alkyl group, a substituted C₁-C₁₀ alkoxy group, a substituted phenyl group, a substituted naphthyl group, a substituted carbazolyl group, a substituted fluorenyl group, or a substituted pyrenyl group which have at least one substituent that is a halogen atom, a cyano group, a hydroxyl group, a C₁-C₁₀ alkyl group, a C₁-C₁₀ alkoxy group, a phenyl group, a naphthyl group, or an anthryl group; or —N(Q₂)(Q₃), but is not limited thereto. In addition, Q₂ and Q₃ may be a methyl group, a phenyl group, a naphthyl group, or an anthryl group.

Ar₂ in the formula —(Ar₁)ₙ—Ar₂— and Ar₁₂ in the formula —(Ar₁₁)ₘ—Ar₁₂— are as defined above in connection with Q₁.

Also, n in the formula —(Ar₁)n-Ar₂— and m in the formula —(Ar₁₁)ₘ—Ar₁₂— may each independently be an integer from 0 to 10. For example, n and m may each independently be 0, 1, 2, 3, 4, or 5, but are not limited thereto.

Also, n groups of Ar₁ in the formula —(Ar₁)ₙ—Ar₂— may be identical to or different from each other. For example, when n is 2, the two groups of Ar₁ in —(Ar₁)ₙ— may both be phenylene groups, or one of the two may be —N(Q₁)- and the other may be a phenylene group. The descriptions of —(Ar₁₁)ₘ—Ar₁₂— may be the same as those of —(Ar₁)ₙ—Ar₂— above.

R₁ through R₃, R₁₁ through R₁₅, R₁₇, R₁₈, and R₂₁ through R₂₉ in Formulae 41 and 42 may be defined as described above in connection with Q₁.

For example, R₁₃ may be a phenyl group, a naphthyl group, or an anthryl group, but is not limited thereto.

For example, R₂₈ and R₂₉ may each independently be a hydrogen atom, a methyl group, an ethyl group, a methoxy group, an ethoxy group, a phenyl group, a naphthyl group, or an anthryl group, but are not limited thereto.

L₁ and L₂ in Formulae 41 and 42 may be defined as described above in connection with Ar₁ and A₁₁.

For example, L₁ and L₂ may each independently be a phenylene group, a carbazolylene group, or a phenylcarbazolylene group, but are not limited thereto.

In Formulae 41 and 42, a and b may each independently be an integer from 0 to 10. For example, a and b may each independently be 0, 1, 2, or 3, but are not limited thereto.

For example, in Formula 42, Ar₁ in the formula —(Ar₁)ₙ—Ar₂— for R₁₀ and Ar₁₁ in the formula —(Ar₁₁)ₘ—Ar₁₂— for R₁₆ may each independently be a phenylene group; a carbazolylene group; a fluorenylene group; a methylfluorenylene group; a pyrazolylene group; a phenylpyrazolylene group; —N(Q₁)-, wherein Q₁ is hydrogen, a phenyl group, a fluorenyl group, a dimethylfluorenyl group, a diphenylfluorenyl group, a carbazolyl group, or a phenylcarbazolyl group; a diphenylfluorenylene group; a triazinylene group; a methyltriazinylene group; a phenyltriazinylene group; a tetrafluorophenylene group; an ethylene group; or a methylphenylene group, wherein n and m may each independently be 0, 1, 2, 3, 4, 5 or 6, and Ar₂ and Ar₁₂ may each independently be hydrogen, a cyano group, a fluoro group, a phenyl group, a cyanophenyl group, a naphthyl group, an anthryl group, a methyl group, a pyridinyl group, a carbazolyl group, a phenylcarbazolyl group, a fluorenyl group, a dimethylfluorenyl group, or a diphenylfluorenyl group. R₁₁, R₁₂, R₁₄, R₁₅, R₁₇, R₁₈, R₂₁ through R₂₇ may be hydrogen; R₁₃ may be a phenyl group, a naphthyl group, or an anthryl group; R₂₈ and R₂₉ may each independently be hydrogen, a methyl group, an ethyl group, a methoxy group, an ethoxy group, a phenyl group, a naphthyl group, or an anthryl group; L₁₁ may be a phenylene group; and b may be 0 or 1.

In an embodiment, one or more of Compounds 1 through 37 below may be used for the hole transporting compound, but the hole transporting compound not limited thereto:

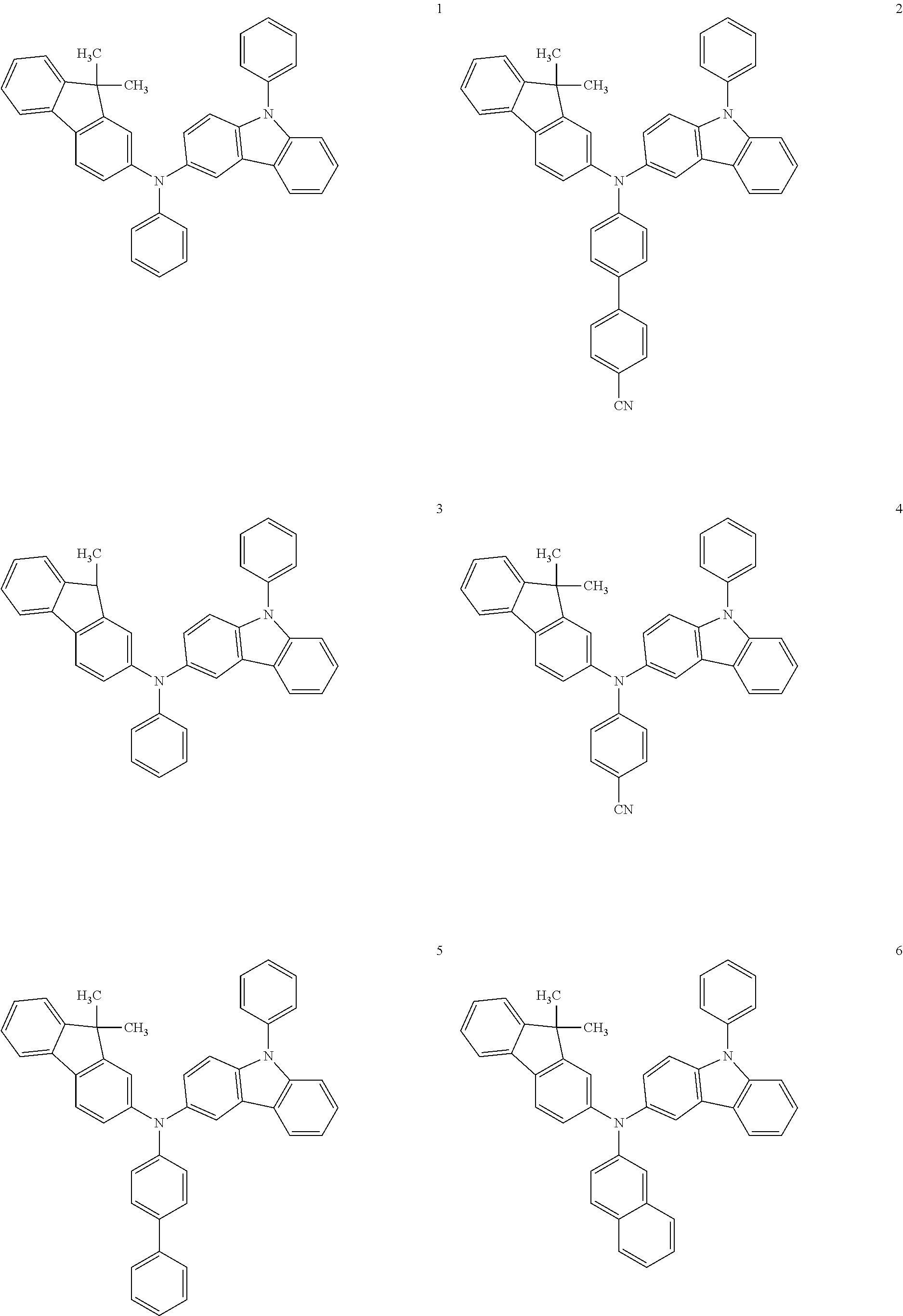

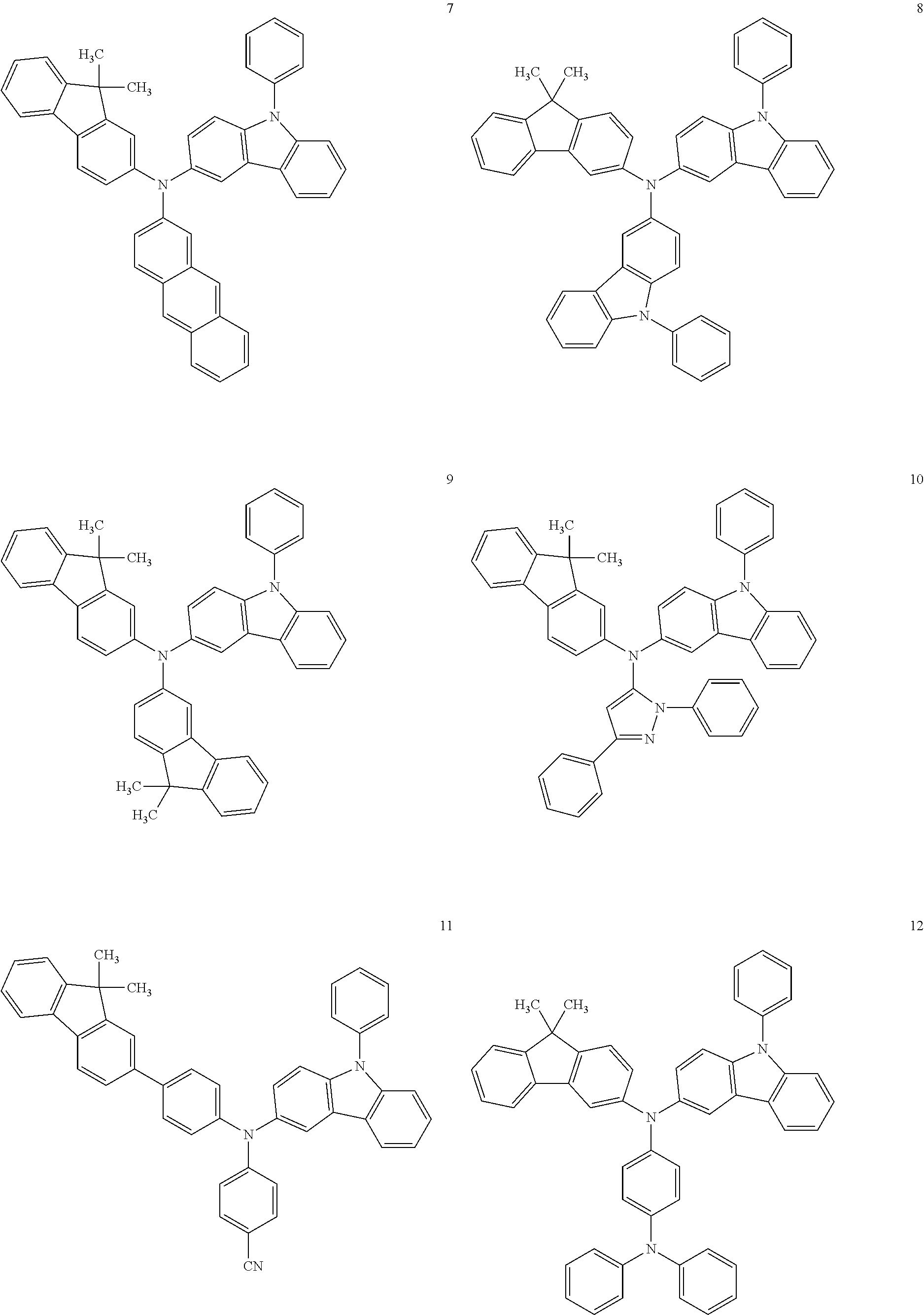

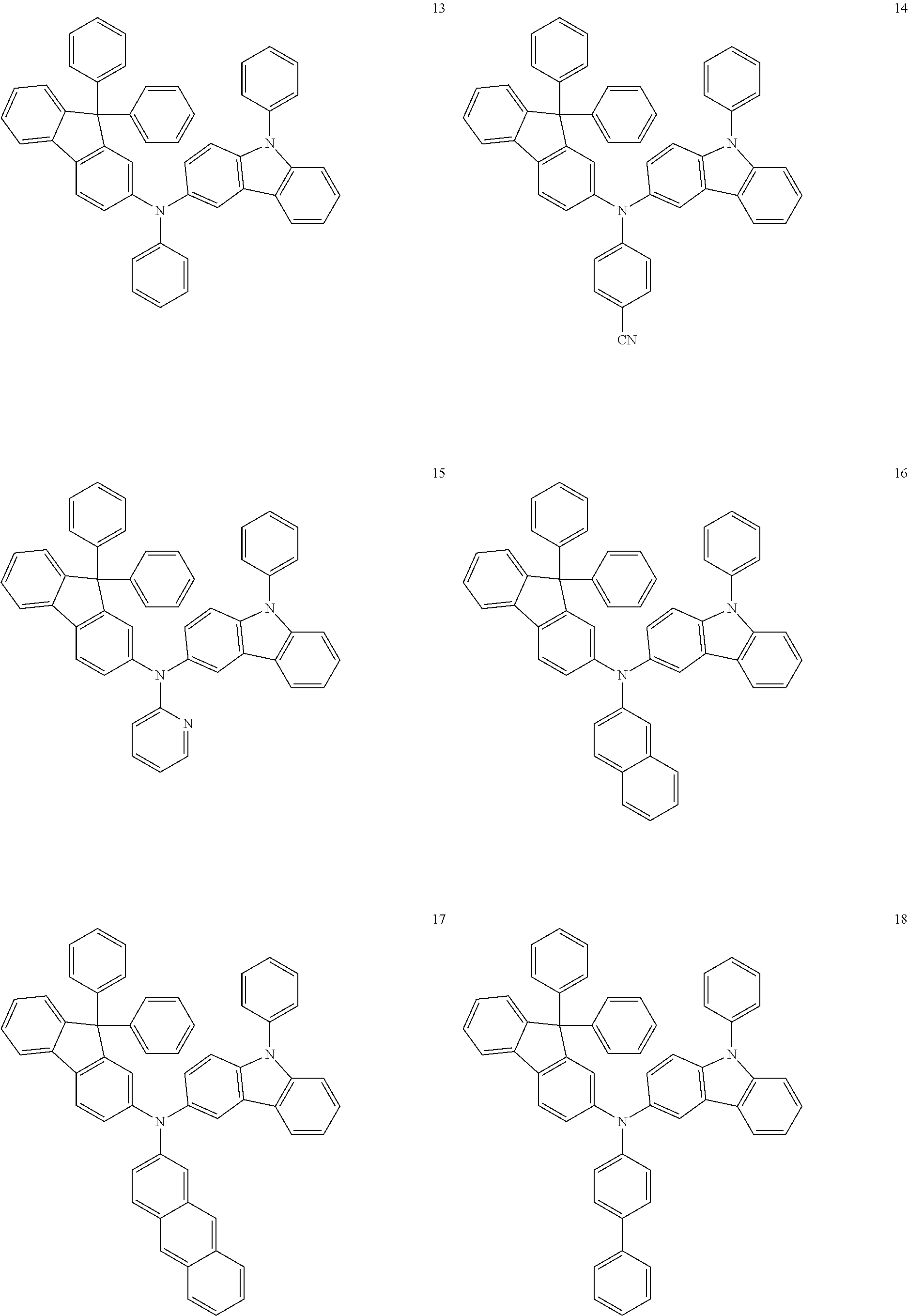

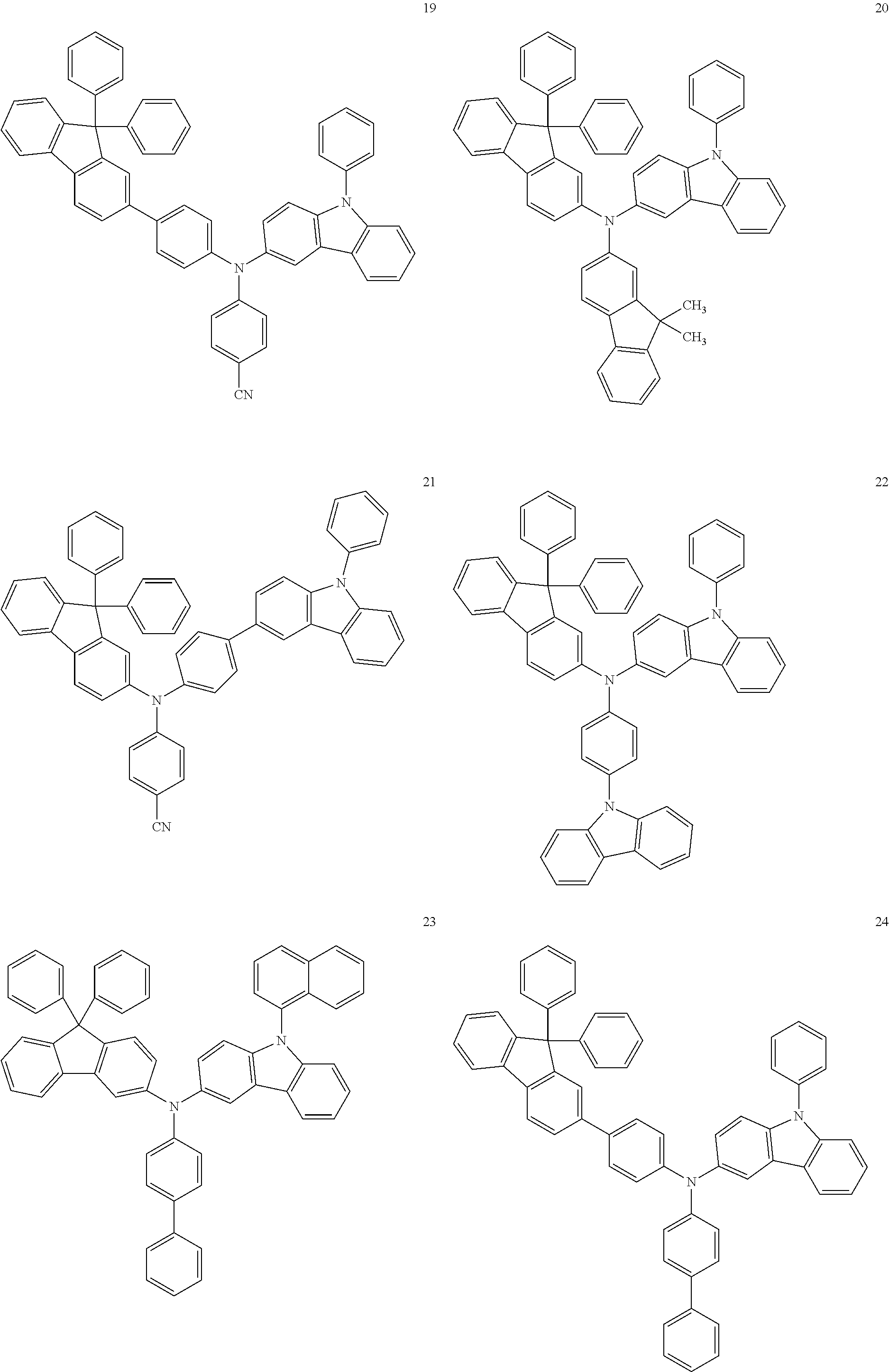

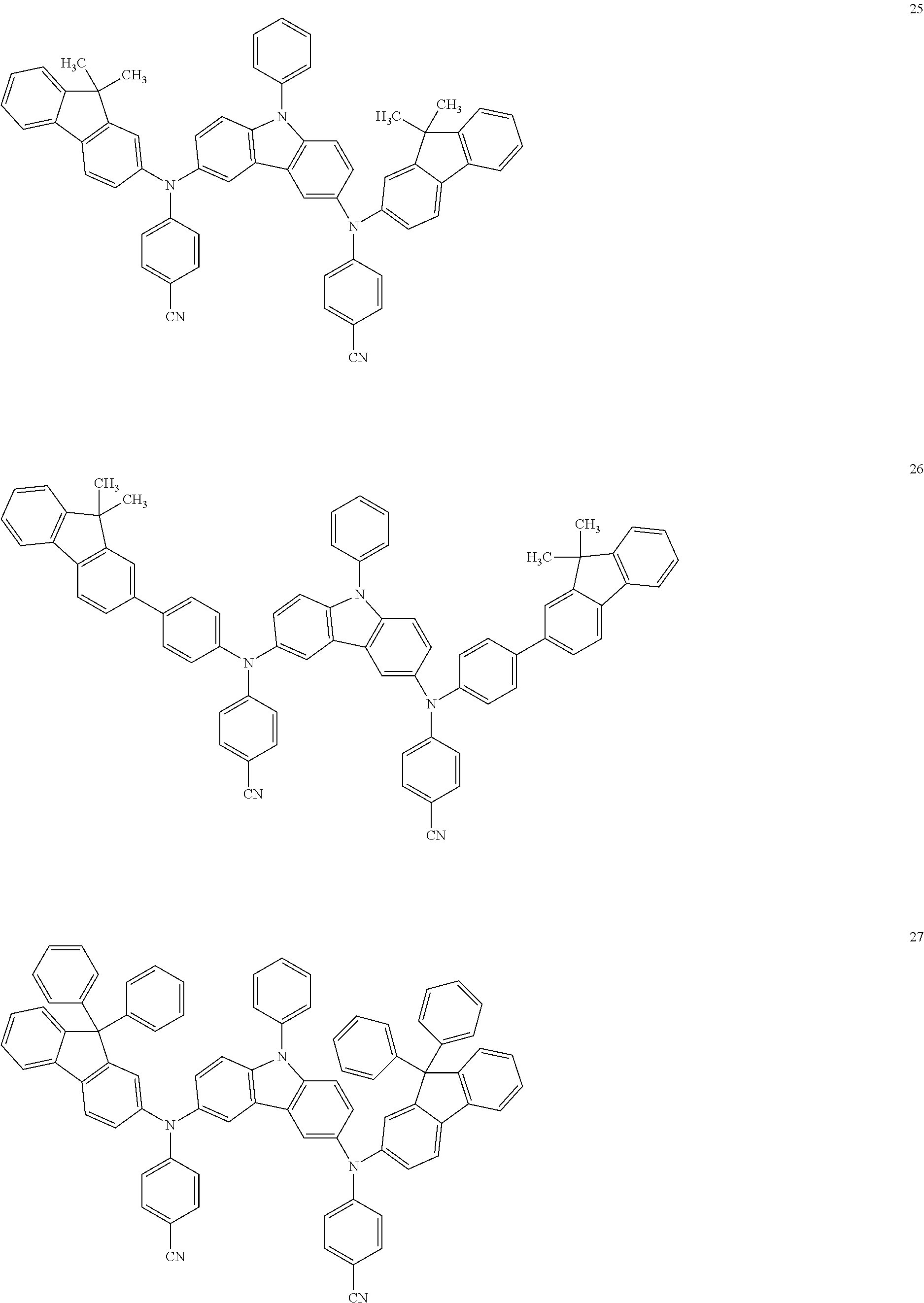

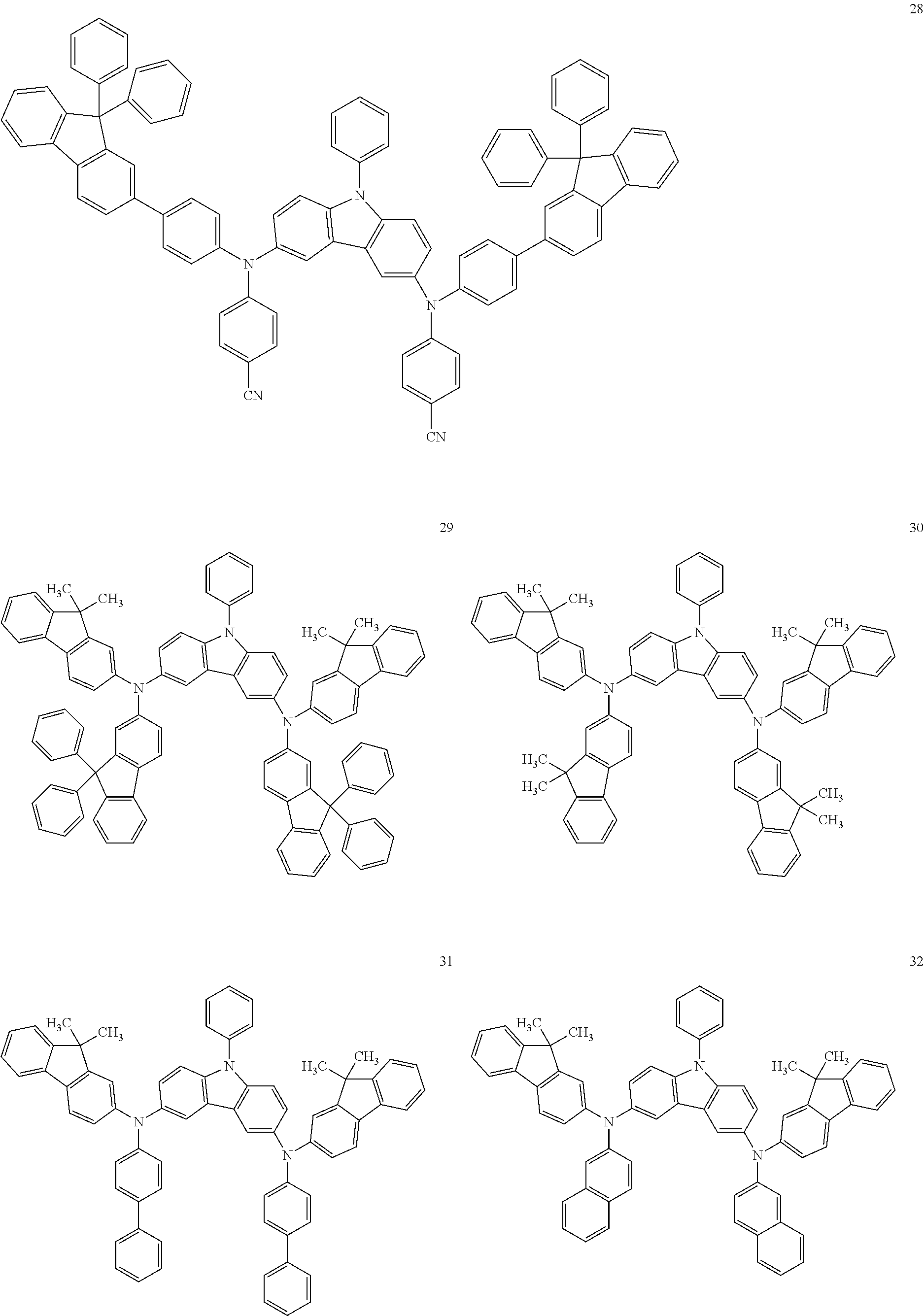

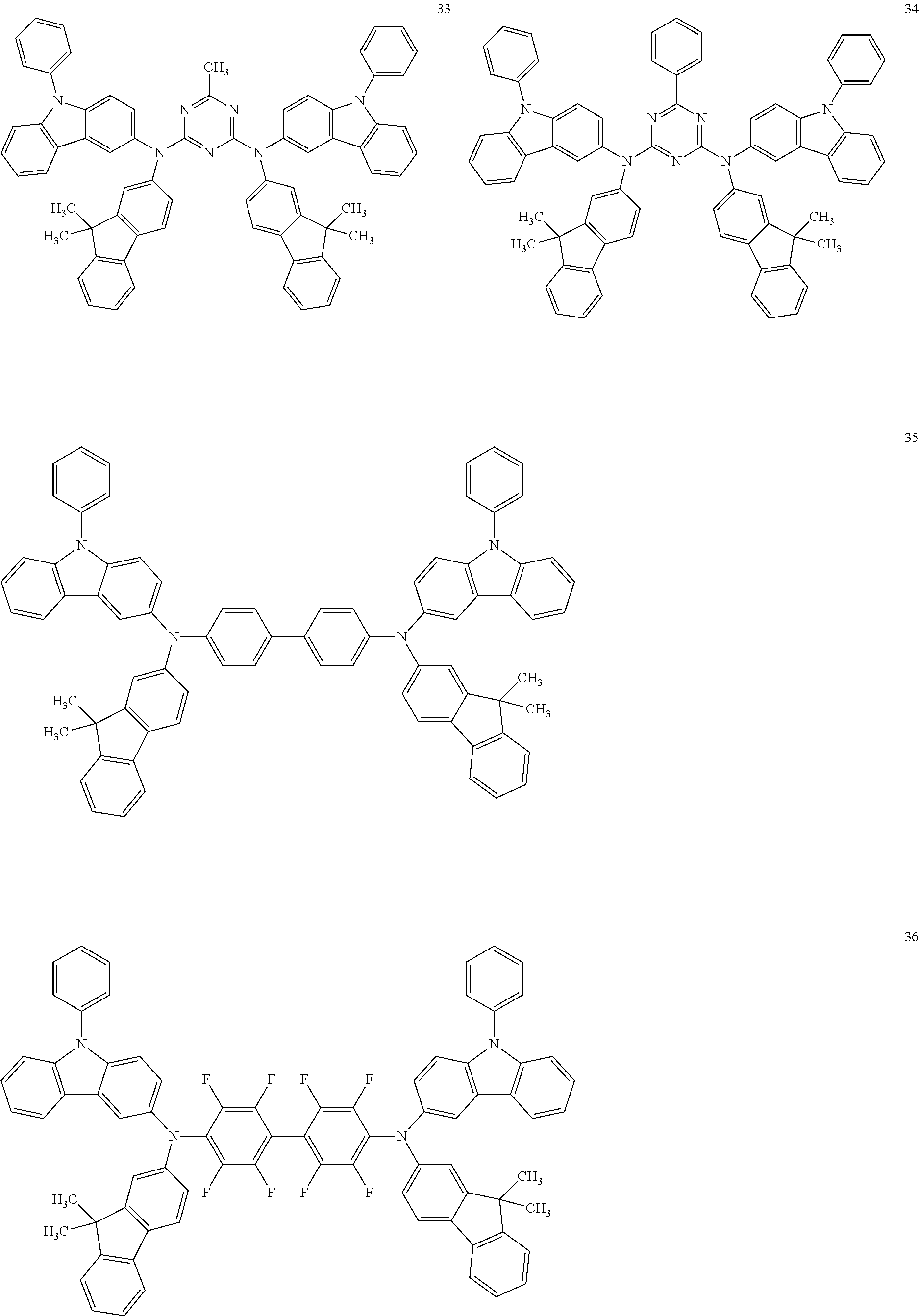

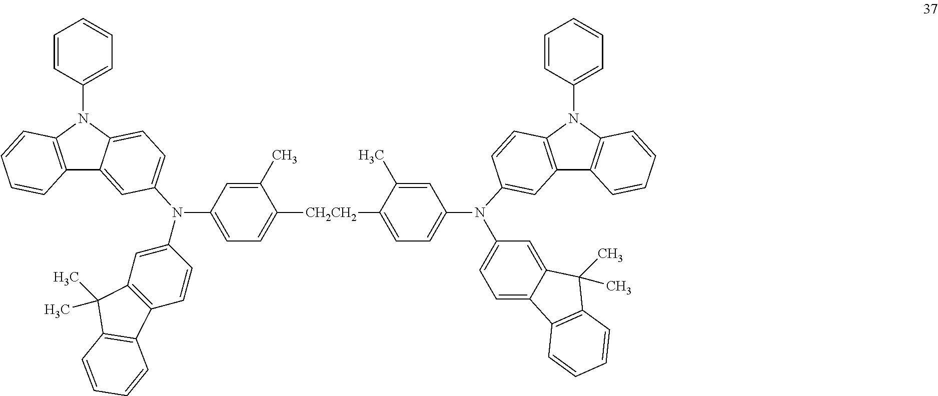

When the first layer 6 includes a hole transporting material described above in addition to the cyano group-containing compound, the amount of the cyano group-containing compound in the first layer 6 may be about 0.1 to about 20 parts by weight, for example, about 0.5 to about 15 parts by weight, or about 0.5 to about 10 parts by weight, based on 100 parts by weight of the first layer 6. With such an amount of the cyano group-containing compound, the driving voltage may be satisfactorily decreased, and the emission and power efficiencies may be satisfactorily improved.

The thickness of the first layer 6 may be about 10 Å to about 2,100 Å, for example, about 10 Å to about 500 Å, or about 20 Å to about 200 Å. With such a thickness of the first layer 6, the driving voltage may be satisfactorily decreased, and the emission and power efficiencies may be satisfactorily improved.

The organic layer 7 may be disposed on the first layer 6. The term “organic layer” used throughout the specification refers to any intervening layer between the first electrode 5 and the second electrode 9 (but excluding the first layer 6 described above). The organic layer 7 may be formed of pure organic materials, and may further include a metal complex.

The organic layer 7 may include an emission layer (EML) and an electron transport layer (ETL).

A distance between the first layer 6 and the EML may be 50 Å or greater, for example, 100 Å or greater, or about 100 Å to about 2,500 Å. With such a distance between the first layer 6 and the EML, quenching of excitons in the emission layer caused by the cyano group-containing compound included in the first layer 6 may be substantially prevented. Thus, the OLED may have excellent quality.

The organic layer 7 may further include at least one of a hole injection layer (HIL), a hole transport layer (HTL), a hole blocking layer (HBL), and an electron injection layer (EIL), in addition to the EML and the ETL. The hole injection layer (HIL), the hole transporting layer (HTL), and the first layer 6 may have hole injection and hole transporting functions.

For example, at least one of the HIL and the HTL may be further disposed between the first layer 6 and the EML. For example, the HTL may be further disposed between the first layer 6 and the EML, but is not limited thereto.

The HIL may be formed on the first layer 6 by vacuum deposition, spin coating, casting, Langmuir-Blodgett (LB) deposition, or the like.

When the HIL is formed using vacuum deposition, the deposition conditions may vary according to a compound that is used to form the HIL, and the structure and thermal properties of the HIL to be formed. In general, however, conditions for vacuum deposition may include a deposition temperature of 100 to 500° C., a pressure of 10⁻⁸ to 10⁻³ torr, and a deposition rate of 0.01 to 100 Å/sec.

When the HIL is formed using spin coating, the coating conditions may vary according to a compound that is used to form the HIL, and the structure and thermal properties of the HIL to be formed. In general, however, the coating rate may be in the range of 2,000 to 5,000 rpm, and a temperature for heat treatment which is performed to remove a solvent after coating may be in the range of 80 to 200° C.

Examples of the material that can be used to form the HIL include a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), TDATA, 2T-NATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline)/poly(4-styrenesulfonate (PANI/PSS), but are not limited thereto.

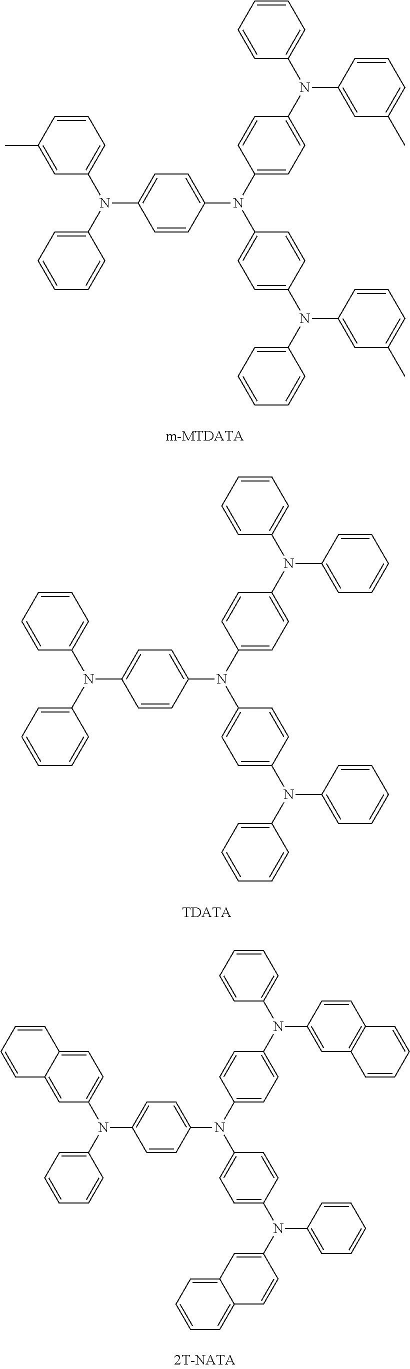

The thickness of the HIL may be about 50 to 1,000 Å, for example, about 100 to about 2,500 Å. With such a thickness of the HIL, the HIL may have excellent hole injecting ability without a substantial increase in driving voltage.

Then, a HTL may be formed on the HIL or on the first layer 6 by vacuum deposition, spin coating, casting, Langmuir-Blodgett (LB) deposition, or the like. When the HTL is formed using vacuum deposition or spin coating, the conditions for deposition and coating may be similar to those for the formation of the HIL, although the conditions for the deposition and coating may vary according to the material that is used to form the HTL.

One or more of the compounds represented by Formula 41 or 42 described above may be used to form the HTL.

The thickness of the HTL may be about 50 to 1,000 Å, for example, about 100 to about 2,500 Å. With such a thickness of the HTL, the HTL may have a satisfactory hole transporting ability without a substantial increase in driving voltage.

Then, the EML may be formed on the HTL by using vacuum deposition, spin coating, casting, LB deposition, or the like. When the EML is formed using vacuum deposition or spin coating, the conditions for deposition and coating may be similar to those for the formation of the HIL, although the conditions for deposition and coating may vary according to the material that is used to form the EML.

The EML may include a blue dopant and a blue host.

The blue host may be a compound represented by Formula 202 below, but is not limited thereto. Examples of the blue host may include 9,10-di-(2-naphthyl)anthracene (ADN), 2-methyl-9,10-di-(2-naphthyl)anthracene (MADN), 2-tert-butyl-9,10-bis(13-naphthyl)-anthracene (TBADN), and 9,10,10-tetraphenyl-2,2-bianthracene (TPBA).

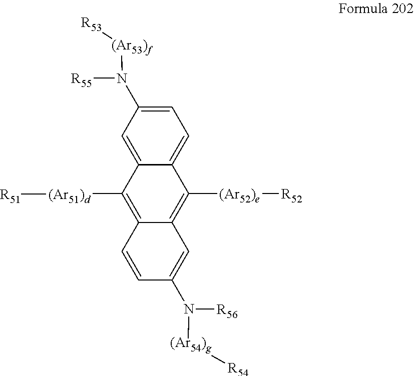

In Formula 202, Ar₅₁, A₅₂, Ar₅₃ and Ar₅₄ may each independently be a phenylene group, a naphthylene group, an anthrylene group, or a phenyl-substituted anthrylene group, but are not limited thereto.

R₅₁ through R₅₆ may each independently be a hydrogen atom, a methyl group, an ethyl group, a propyl group, a butyl group, a phenyl group, a naphthyl group, an anthryl group, a pyrenyl group, a carbazolyl group, or —N(Q₂)(Q₃), wherein Q₂ and Q₃ are each independently a methyl group, a phenyl group, a naphthyl group, or an anthryl group.

In Formula 202, d, e, f, and g may each independently be an integer from 0 to 10. For example, d, e, f, and g may each independently be 0, 1, or 2, but are not limited thereto.

The blue dopant may be a compound represented by Formula 201, but is not limited thereto. For example, the blue dopant may be a compound represented by Formula 203 or 204.

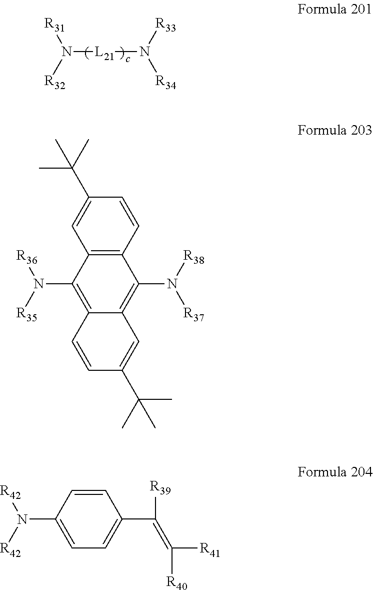

R₃₅ and R₄₂ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₅-C₃₀ aryl group, or a substituted or unsubstituted C₄-C₃₀ heteroaryl group. In an implementation, R₃₅ and R₄₂ may each independently be hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₆-C₃₀ aryl group, or a substituted or unsubstituted C₄-C₃₀ heteroaryl group

In Formula 201, L₂₁ may be a substituted or unsubstituted C₁-C₃₀ alkylene group, a substituted or unsubstituted C₂-C₃₀ alkenylene group, a substituted or unsubstituted C₅-C₃₀ arylene group, or a substituted or unsubstituted C₄-C₃₀ heteroarylene group; c may be an integer from 1 to 20; c groups of L₂₁ in -(L₂₁)_{c}- may be identical to or different from each other; and R₃₁ through R₃₄ may each independently be a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₅-C₃₀ aryl group, or a substituted or unsubstituted C₄-C₃₀ heteroaryl group. In an implementation, L₂₁ may be a substituted or unsubstituted C₁-C₃₀ alkylene group, a substituted or unsubstituted C₂-C₃₀ alkenylene group, a substituted or unsubstituted C₆-C₃₀ arylene group, or a substituted or unsubstituted C₄-C₃₀ heteroarylene group; and R₃₁ through R₃₄ may each independently be a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₆-C₃₀ aryl group, or a substituted or unsubstituted C₄-C₃₀ heteroaryl group.

In Formula 201, L₂₁ may be an ethenylene group, a propenylene group, or a phenylene group.

In Formula 201, c may be 1, 2, 3, 4, 5, or 6.

In Formula 201, R₃₁ through R₃₄ may each independently be a hydrogen atom, a methyl group, an ethyl group, a propyl group, a butyl group, a methoxy group, an ethoxy group, a propoxy group, a butoxy group, a phenyl group, a naphthyl group, or an anthryl group.

In Formula 201, c groups of L₂₁ in -(L₂₁)_{c}- may be identical to or different from each other. For example, when c is 2, the two groups of L₂₁ may both be phenylene groups, or one of the two may be a phenylene group, and the other may be an ethenylene group.

The compound represented by Formula 201 may be Compound 40 below.

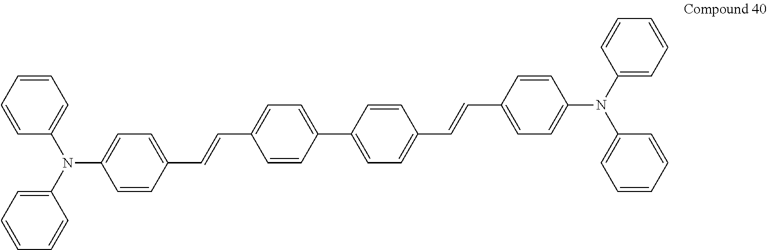

When a dopant and a host are used together as materials for the EML, the amount of the dopant may be about 0.01 to about 15 parts by weight, based on 100 parts by weight of the host, but is not limited thereto.

The thickness of the EML may be about 100 to about 1,000 Å, for example, about 200 to about 600 Å. With such a thickness of the EML, the EML may have excellent light emitting ability without a substantial increase in driving voltage.

When a phosphorescent dopant is also used to form the EML, a HBL may be formed between the HTL and the EML by using vacuum deposition, spin coating, casting, Langmuir-Blodgett (LB) deposition, or the like, in order to prevent diffusion of triplet excitons or holes into an ETL. When the HBL is formed using vacuum deposition or spin coating, the conditions for deposition and coating may be similar to those for the formation of the HIL, although the conditions for deposition and coating may vary according to the material that is used to form the HBL. Examples of materials for forming the HBL include an oxadiazole derivative, a triazole derivative, and a phenanthroline derivative, but are not limited thereto.

The thickness of the HBL may be about 50 to 1,000 Å, for example, about 100 to about 400 Å. With such a thickness of the HBL, the HBL may have an excellent hole blocking ability without a substantial increase in driving voltage.

Then, an ETL may be formed on the HBL or EML by vacuum deposition, spin coating, casting, or the like. When the ETL is formed using vacuum deposition or spin coating, the deposition and coating conditions may be similar to those for formation of the HIL, although the deposition and coating conditions may vary according to a material that is used to form the ETL.

A material for forming the ETL may include an anthracene-based compound and a quinolate-based compound that can stably transport electrons injected from an electron injecting electrode (cathode).

The anthracene-based compound may be at least one of a compound represented by Formula 101 below and a compound represented by Formula 102 below, but is not limited thereto:

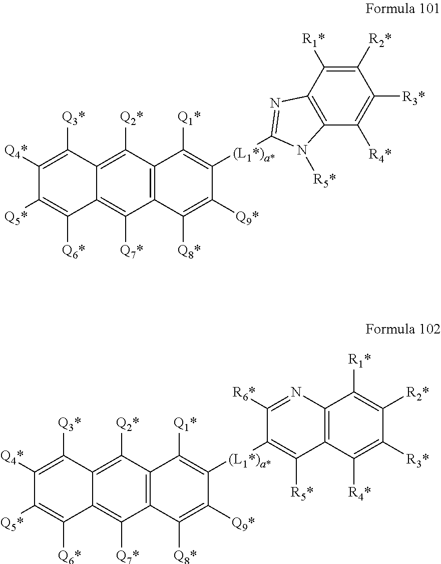

In Formulae 101 and 102, R*₁ through R*₆ may each independently be a hydrogen atom, a halogen atom, a hydroxyl group, a cyano group, a substituted or unsubstituted C₁-C₃₀ alkyl group, a substituted or unsubstituted C₁-C₃₀ alkoxy group, a substituted or unsubstituted C₁-C₃₀ acyl group, a substituted or unsubstituted C₂-C₃₀ alkenyl group, a substituted or unsubstituted C₂-C₃₀ alkynyl group, a substituted or unsubstituted C₆-C₃₀ aryl group, or a substituted or unsubstituted C₃-C₃₀ heteroaryl group, wherein at least two adjacent groups of R*₁ through R*₆ may be linked together to form a saturated or unsaturated ring; L*₁ may be a single bond, a substituted or unsubstituted C₁-C₃₀ alkylene group, a substituted or unsubstituted C₆-C₃₀ arylene group, or a substituted or unsubstituted C₃-C₃₀ heteroarylene group; Q*₁ through Q*₉ may each independently be a hydrogen atom, a substituted or unsubstituted C₆-C₃₀ aryl group, or a substituted or unsubstituted C₃-C₃₀ heteroaryl group; and a* may be an integer from 1 to 10.

For example, the anthracene-based compound may be at least one of a compound represented by Formula 103 below and a compound represented by Formula 104 below.

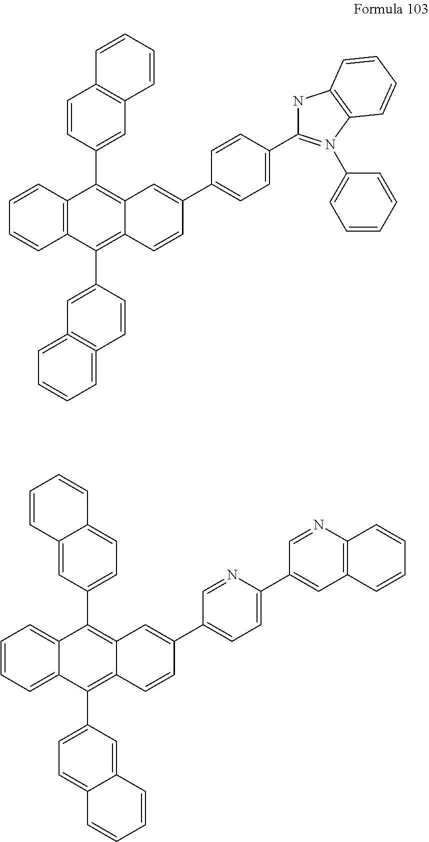

The quinolate-based compound may be at least one of lithium quinolate (LiQ) and LiF, but is not limited thereto.

The amounts of the anthracene-based compound and the quinolate-based compound may vary depending on the amount of holes injected from an anode to achieve optimum balance between carriers, and a ratio of the amount of the anthracene-based compound to the amount of the quinolate-based compound may be about 10:5 to about 10:15, for example, about 10:10 taking into consideration a deposition process. As the amount of the quinolate-based compound increases, a hole blocking ability of the HBL may increase, but an electron mobility of the ETL may decrease, thereby increasing driving voltage of the OLED and reducing efficiency of the OLED. As the amount of the quinolate-based compound decreases, the ETL may exhibit dominant physical properties by the effect of the anthracene-based compound on the electron mobility of the ETL, thereby increasing driving voltage of the OLED, and reducing efficiency and lifetime of the OLED.

The thickness of the ETL may be about 100 to about 1,000 Å, for example, about 150 to about 500 Å. With such a thickness of the ETL, the ETL may have satisfactory electron transporting ability without a substantial increase in driving voltage.

Then, an EIL may be formed on the ETL. The EIL may be formed of a suitable material facilitating injection of electrons from a cathode.

Examples of materials for forming the EIL include LiF, NaCl, CsF, Li₂O, and BaO, which are known in the art. Deposition and coating conditions for forming the EIL may be similar to those for the formation of the HIL, although the deposition and coating conditions may vary according to a material that is used to form the EIL.

The thickness of the EIL may be about 1 to about 100 Å, for example, about 5 to about 90 Å. With such a thickness of the EIL, the EIL may have satisfactory electron injecting ability without a substantial increase in driving voltage.

The second electrode 9 may be disposed on the organic layer 7. The second electrode 9 may be a cathode, which is an electron injecting electrode. A metal for forming the second electrode 9 may be a metal, an alloy, or an electrically conductive compound, which have a low-work function, or a mixture thereof. In this regard, the second electrode 9 may be formed of lithium (Li), magnesium (Mg), aluminum (Al), aluminum (Al)-lithium (Li), calcium (Ca), magnesium (Mg)-indium (In), magnesium (Mg)-silver (Ag), or the like, and may be formed as a thin film type transmissive electrode. In addition, the transmissive electrode may be formed of indium tin oxide (ITO) or indium zinc oxide (IZO) to manufacture a top-emission type light-emitting device.

For example, the OLED may have a structure including: the first electrode;

a first layer including one or more cyano group-containing compounds represented by Formulae 1A through 20B, wherein the first layer may further include the hole transporting compound represented by Formula 42; a HTL including the compound represented by Formula 42; an EML including a blue host (the compound represented by Formula 202) and a blue dopant (the compound represented by Formula 202); an ETL including the anthracene-based compound represented by Formula 101 and LiQ; an EIL; and a second electrode, which are sequentially stacked in this order. Thus, the OLED may emit excellent blue light due to the structure.

The OLED has been described with reference to FIG. 1, but is not limited thereto.

For example, the OLED 10 may further include at least one of a HIL and a HTL between the first electrode 5 and the first layer 6. For example, an OLED according to an embodiment may have a structure including: a substrate, a first electrode, a first HTL, a first layer, a second HTL, an EML, an ETL, an EIL, and a second electrode, which are sequentially stacked in this order.

In another embodiment, the OLED may include multiple first layers. For example, an OLED according to an embodiment may have a structure including: a substrate, a first electrode, a first layer, a HTL, another first layer, another HTL, an EML, an ETL, an EIL, and a second electrode, which are sequentially stacked in this order.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

### COMPARATIVE EXAMPLE 1

A 15 Ω/cm² (1,200 Å) ITO glass substrate (available from Corning Co.) was cut to a size of 50 mm×50 mm×0.7 mm, ultrasonically washed with isopropyl alcohol for 5 minutes and then with pure water for 5 minutes, and washed again with UV ozone for 30 minutes.

NPB was vacuum-deposited on the ITO glass substrate to form a HTL having a thickness of 750 Å.

97 wt % of Compound 56 and 3 wt % of Compound 58 were deposited on the HTL to form an EML having a thickness of 200 Å.

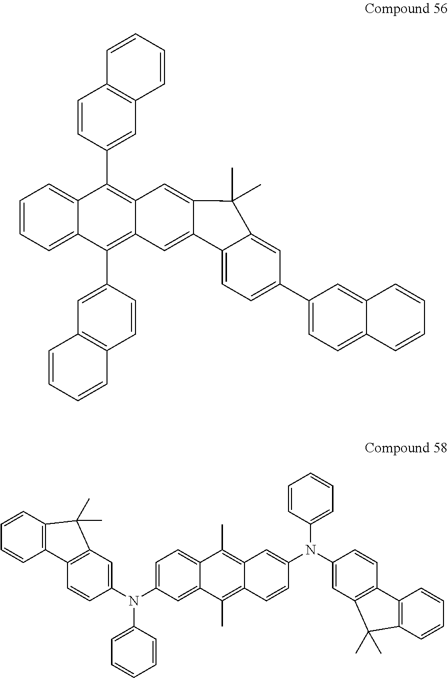

Alq₃ was vacuum-deposited on the EML to form an ETL having a thickness of 300 Å.

LiQ was vacuum-deposited on the ETL to form an EIL having a thickness of 5 Å and Mg and Ag were vacuum-deposited on the EIL to form a cathode having a thickness of 160 Å. Next, Alq₃ was deposited on the cathode to form a protection layer having a thickness of 600 Å, thereby completing the manufacture of an OLED.

### COMPARATIVE EXAMPLE 2

A 15 Ω/cm² (1,200 Å) ITO glass substrate (available from Coming Co.) was cut to a size of 50 mm×50 mm×0.7 mm, ultrasonically washed with isopropyl alcohol for 5 minutes and then with pure water for 5 minutes, and washed again with UV ozone for 30 minutes.

A first layer, instead of the HIL, was formed on the ITO glass substrate to a thickness of 100 Å, wherein the first layer contained Compound 5 above and 1 part by weight of the compound represented by Formula 20A (R₁₀₉ is —F) based on 100 parts by weight of the first layer.

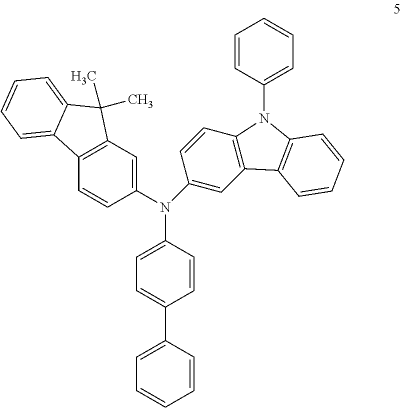

NPB was vacuum-deposited on the first layer to form a HTL having a thickness of 750 Å.

97 wt % of Compound 56 above and 3 wt % of Compound 58 above were deposited on the HTL to form an EML having a thickness of 200 Å.

Alq₃ was vacuum-deposited on the EML to form an ETL having a thickness of 300 Å.

LiQ was vacuum-deposited on the ETL to form an EIL having a thickness of 5 Å and Mg and Ag were vacuum-deposited on the EIL to form a cathode having a thickness of 160 Å. Next, Alq₃ was deposited, on the cathode to form a protection layer having a thickness of 600 Å, thereby completing the manufacture of an OLED.

### COMPARATIVE EXAMPLE 3

A 15 Ω/cm² (1,200 Å) ITO glass substrate (available from Corning Co.) was cut to a size of 50 mm×50 mm×0.7 mm, ultrasonically washed with isopropyl alcohol for 5 minutes and then with pure water for 5 minutes, and washed again with UV ozone for 30 minutes.

A first layer, instead of the HIL, was formed on the ITO glass substrate to a thickness of 100 Å, wherein the first layer contained Compound 5 above and 1 part by weight of the compound represented by Formula 20A (R₁₀₉ is —F) based on 100 parts by weight of the first layer.

NPB was vacuum-deposited on the first layer to form a HTL having a thickness of 750 Å.

97 wt % of 9,10-di(naphthalene-2-yl)anthracene (ADN) and 3 wt % of Compound 40 above were deposited on the HTL to form an EML having a thickness of 200 Å.

Alq₃ was vacuum-deposited on the EML to form an ETL having a thickness of 300 Å.

LiQ was vacuum-deposited on the ETL to form an EIL having a thickness of 5 Å and Mg and Ag were vacuum-deposited on the EIL to form a cathode having a thickness of 160 Å. Next, Alq₃ was deposited on the cathode to form a protection layer having a thickness of 600 Å, thereby completing the manufacture of an OLED.

### EXAMPLE 1

A 15 Ω/cm² (1,200 Å) ITO glass substrate (available from Coming Co.) was cut to a size of 50 mm×50 mm×0.7 mm, ultrasonically washed with isopropyl alcohol for 5 minutes and then with pure water for 5 minutes, and washed again with UV ozone for 30 minutes.

A first layer, instead of the HIL, was formed on the ITO glass substrate to a thickness of 100 Å, wherein the first layer contained Compound 5 above and 1 part by weight of the compound represented by Formula 20A (R₁₀₉ is —F) based on 100 parts by weight of the first layer.

NPB was vacuum-deposited on the first layer to form a HTL having a thickness of 750 Å.

97 wt % of 9,10-di(naphthalene-2-yl)anthracene (ADN) and 3 wt % of Compound 40 above were deposited on the HTL to form an EML having a thickness of 200 Å.

ADN and LiQ were vacuum-deposited on the EML to form an ETL having a thickness of 300 Å.

LiQ was vacuum-deposited on the ETL to form an EIL having a thickness of 5 Å, and Mg and Ag were vacuum-deposited on the EIL to form a cathode having a thickness of 160 Å. Next, Alq₃ was deposited on the cathode to form a protection layer having a thickness of 600 Å, thereby completing the manufacture of an OLED.

### EXAMPLE 2

An OLED was manufactured in the same manner as in Example 1, except that 3 parts by weight of the compound represented by Formula 20A was used based on 100 parts by weight of the first layer.

### EVALUATION EXAMPLE

Driving voltages of the OLEDs manufactured according to Comparative Examples 1 through 3 and Examples 1 and 2 were measured using a 238 High-Current Source-Measure unit (available from Keithley Instruments Inc.), and current efficiency and power efficiency thereof were measured using a PR650 Spectroscan Source Measurement Unit (available from PhotoResearch, Inc.). The results are shown in Table 1 below.

TABLE 1

| | Driving | current | Color coordinate |
|---|---|---|---|
| | voltage | efficiency | weight-calculated |
| | (V) | (Cd/A) | efficiency (Cd/Ay) |
| Comparative | 3.8 | 2.9 | 58 |
| Example 1 | | | |
| Comparative | 3.8 | 3.5 | 76 |
| Example 2 | | | |
| Comparative | 3.9 | 3.7 | 81 |
| Example 3 | | | |
| Example 1 | 4.1 | 5.4 | 102 |
| Example 2 | 3.8 | 7.15 | 130 |

Referring to Table 1, the OLEDs of Examples 1 and 2 were found to have lower driving voltages, and higher current efficiency and power efficiency, as compared to the OLEDs of Comparative Examples 1 through 3.

As described above, an OLED according to an embodiment may have excellent driving voltage characteristics, emission efficiency characteristics and power efficiency characteristics.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. An organic light-emitting device, comprising:
a substrate;
a first electrode disposed on the substrate;
a second electrode;
an organic layer disposed between the first electrode and the second electrode, the organic layer including an emission layer and an electron transport layer, the electron transport layer including an anthracene-based compound and a quinolate-based compound; and
at least one first layer disposed between the first electrode and the emission layer, the at least one first layer including a cyano group-containing compound.

2. The organic light-emitting device as claimed in claim 1, wherein the cyano group-containing compound includes at least one compound represented by Formulae 1 through 20: 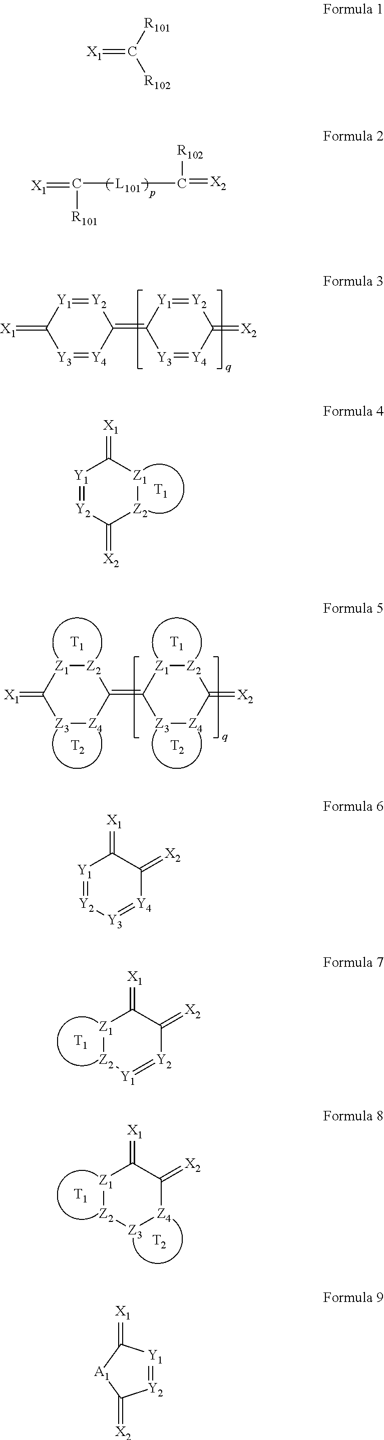 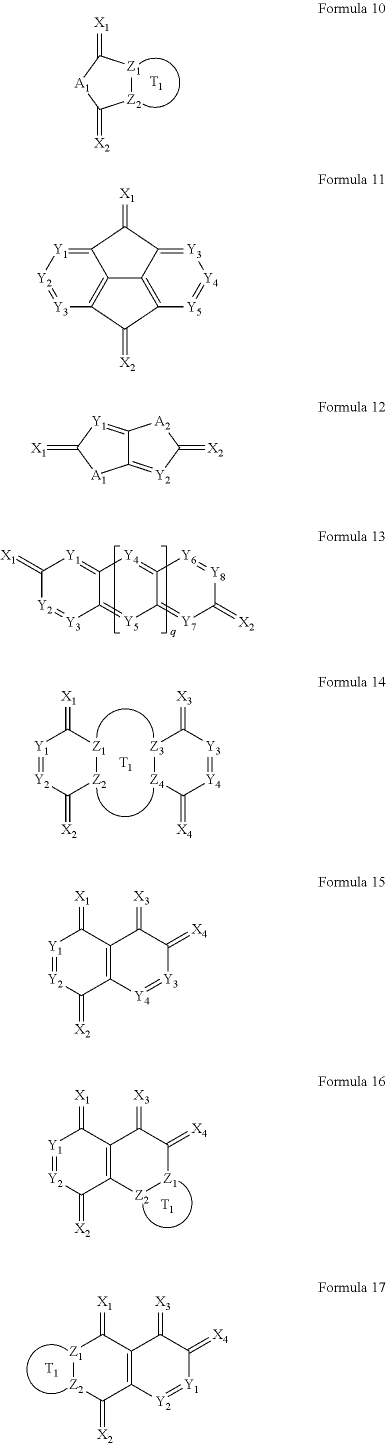 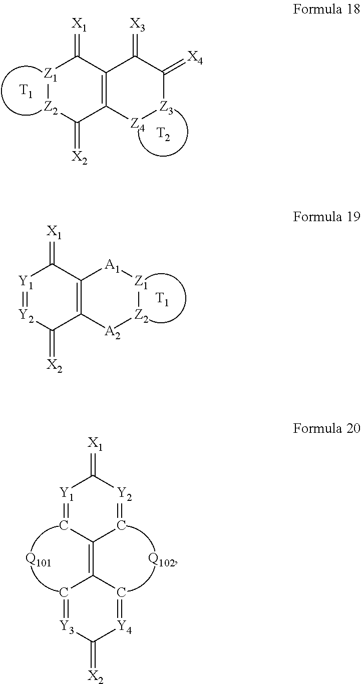
and
wherein, in Formulae 1 through 20,
X₁ through X₄ are each independently compounds represented by Formulae 30A through 30D below;
Y₁ through Y₈ are each independently N or C(R₁₀₃);
Z₁ through Z₄ are each independently C or N;
A₁ and A₂ are each independently —O—, —S—, —N(R₁₀₄), or —C(R₁₀₅)(R₁₀₆)—;
Q₁₀₁ and Q₁₀₂ are each independently a C₂-C₁₀ alkylene group; a C₂-C₁₀ alkenylene group; or a substituted C₂-C₁₀ alkylene group or a substituted C₂-C₁₀ alkenylene group which have at least one substituent that is a halogen atom, a cyano group, a hydroxyl group, a C₁-C₁₀ alkyl group, or a C₁-C₁₀ alkoxy group;
T₁ and T₂ are each independently a C₅-C₃₀ aromatic ring system; a C₂-C₃₀ heteroaromatic ring system; or a substituted C₅-C₃₀ aromatic ring system or a substituted C₂-C₃₀ heteroaromatic ring system which have at least one substituent that is a halogen atom, a cyano group, a hydroxyl group, a C₁-C₁₀ alkyl group, or a C₁-C₁₀ alkoxy group;
p is an integer from 1 to 10;
q is an integer from 0 to 10;
R₁₀₁ through R₁₀₆ are each independently hydrogen; a halogen atom; a cyano group; a hydroxyl group; a C₁-C₁₀ alkyl group; a C₁-C₁₀ alkoxy group; a substituted C₁-C₁₀ alkyl group or a substituted C₁-C₁₀ alkoxy group which have at least one substituent that is a halogen atom, a cyano group, a hydroxyl group, a C₅-C₁₄ aryl group, or a C₂-C₁₄ heteroaryl group; 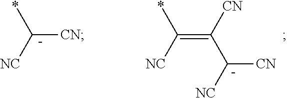
or —N(R₁₀₇)(R₁₀₈), wherein R₁₀₇ and R₁₀₈ are each independently hydrogen, a C₁-C₁₀ alkyl group, a phenyl group, or a biphenyl group;
L₁₀₁ is a C₅-C₁₄ arylene group; a C₅-C₁₄ heteroarylene group; or a substituted C₂-C₁₀ alkenylene group, a substituted C₅-C₁₄ arylene group, or a substituted C₅-C₁₄ heteroarylene group which have at least one substituent that is a halogen atom, a cyano group, a hydroxyl group, a C₁-C₁₀ alkyl group, or a C₁-C₁₀ alkoxy group,

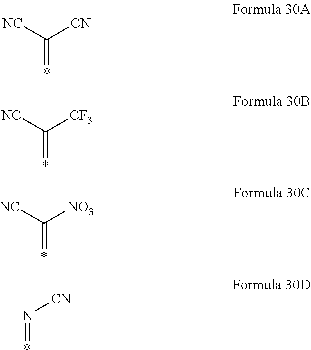

3. The organic light-emitting device as claimed in claim 2, wherein X₁ through X₄ are each independently the compound represented by Formula 30A or the compound represented by Formula 30D.

4. The organic light-emitting device as claimed in claim 2, wherein R₁₀₃ is hydrogen; a halogen atom; a cyano group; a C₁-C₁₀ alkyl group; a C₁-C₁₀ alkoxy group; a substituted C₁-C₁₀ alkyl group or a substituted C₁-C₁₀ alkoxy group which have at least one substituent that is a halogen atom, a cyano group, a phenyl group, a naphthyl group, an anthryl group, a pyridinyl group, a thiophenyl group, or a benzothiophenyl group; or —N(R₁₀₇)(R₁₀₈), wherein R₁₀₇ and R₁₀₈ are each independently hydrogen, a C₁-C₁₀ alkyl group, a phenyl group, or a biphenyl group.

5. The organic light-emitting device as claimed in claim 2, wherein T₁ and T₂ are each independently benzene; naphthalene; anthracene; thiophene; thiadiazole; oxadiazole; or a substituted benzene, a substituted naphthalene, a substituted anthracene, a substituted thiophene, a substituted thiadiazole, or a substituted oxadiazole which have at least one substituent that is a halogen atom, a cyano group, a C₁-C₁₀ alkyl group, or a C₁-C₁₀ alkoxy group.

6. The organic light-emitting device as claimed in claim 2, wherein L₁₀₁ is a thiophenylene group; a benzothiophenylene group; or a substituted thiophenylene group or a substituted benzothiophenylene group which have at least one substituent that is a halogen atom, a cyano group, or a C₁-C₁₀ alkyl group.

7. The organic light-emitting device as claimed in claim 2, wherein the cyano group-containing compound includes at least one compound represented by Formulae 1A through 20B: 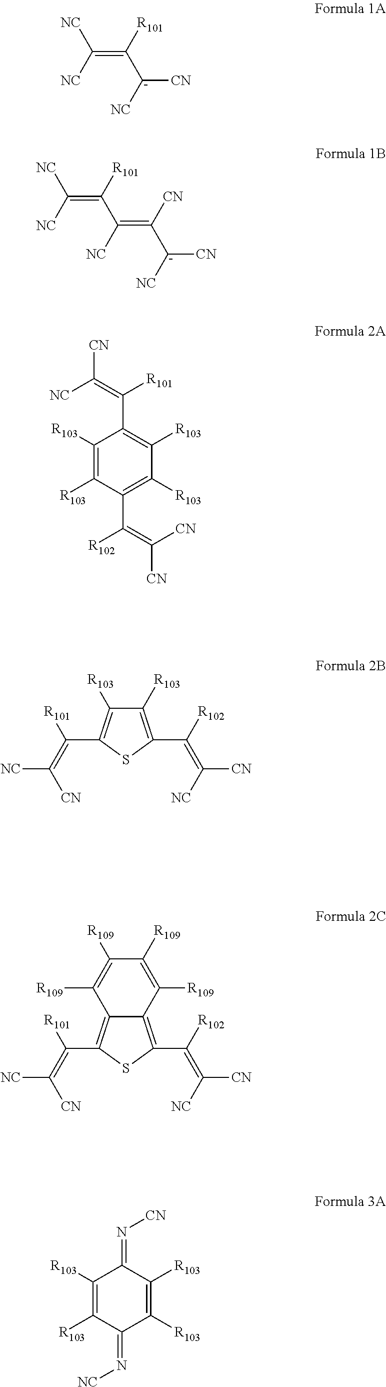 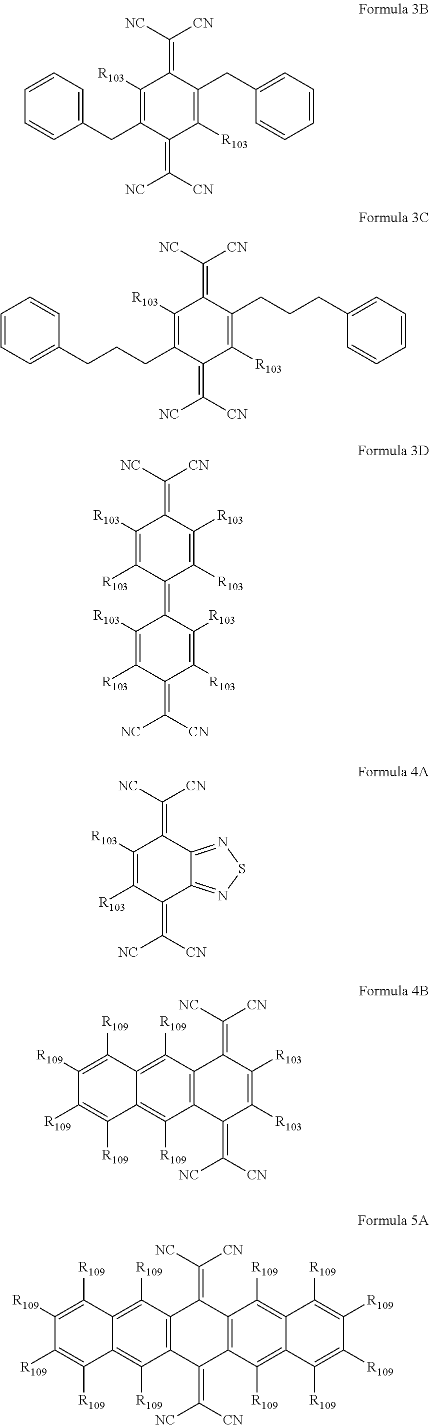 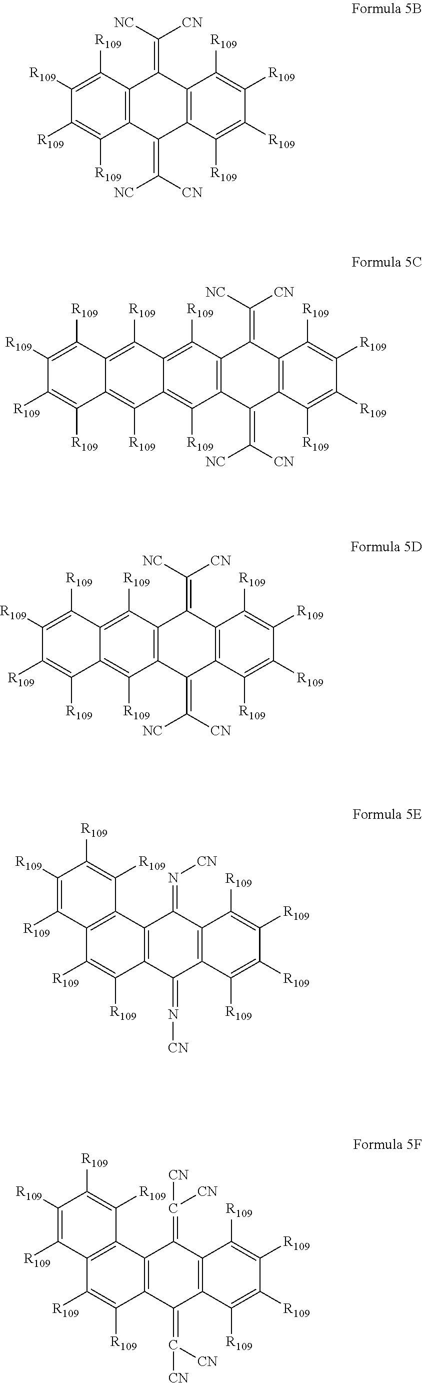 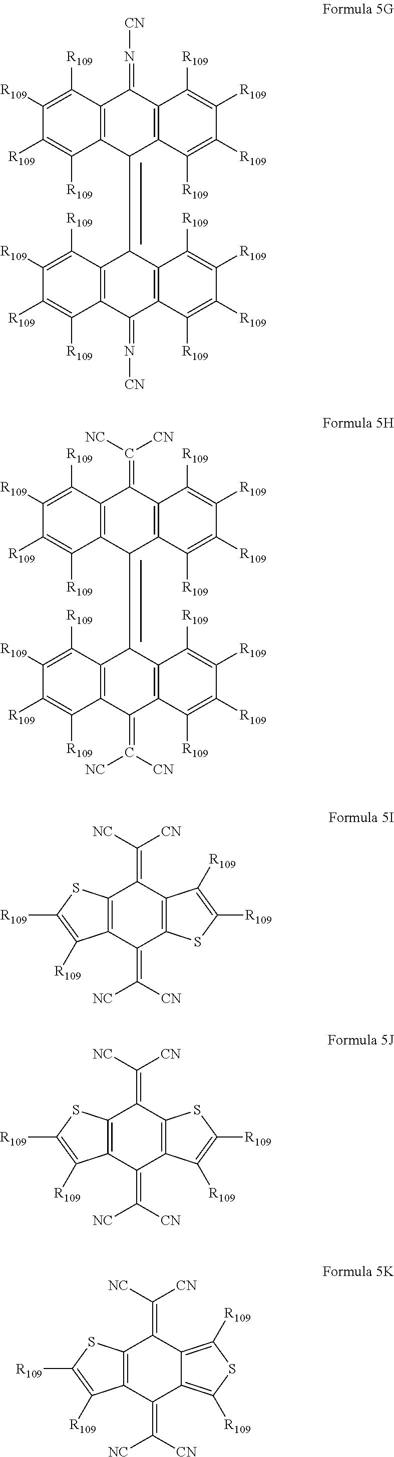 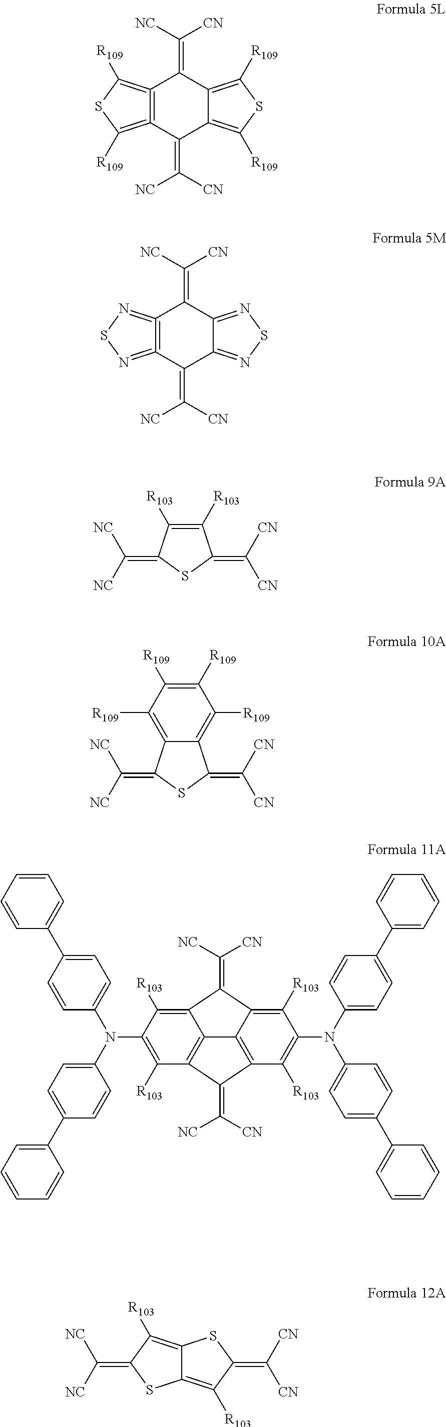 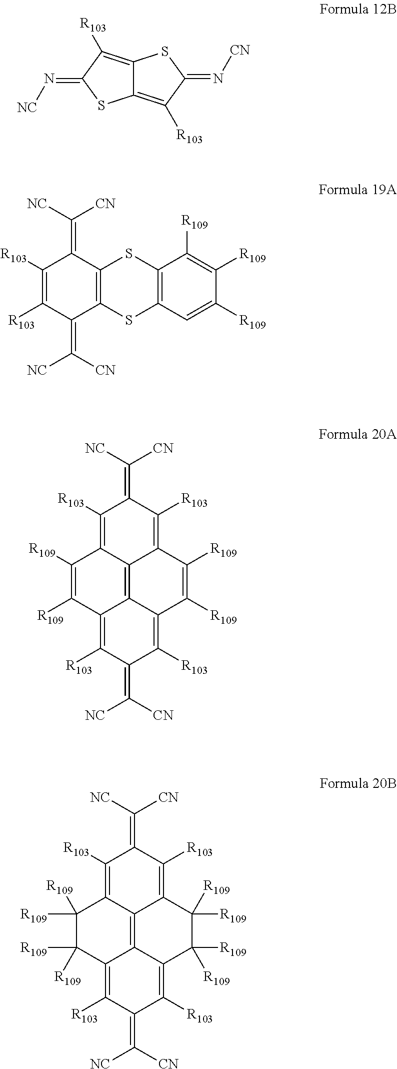
wherein, in Formulae 1A through 20B, R₁₀₃ and R₁₀₉ are each independently a hydrogen atom, —F, a cyano group, a methyl group, an ethyl group, a propyl group, a ethenyl group, a methoxy group, an ethoxy group, or a propoxy group.

8. The organic light-emitting device as claimed in claim 1, wherein the first layer further includes a hole transporting compound.

9. The organic light-emitting device as claimed in claim 8, wherein the hole transporting compound includes,a compound represented by Formula 41 or 42: 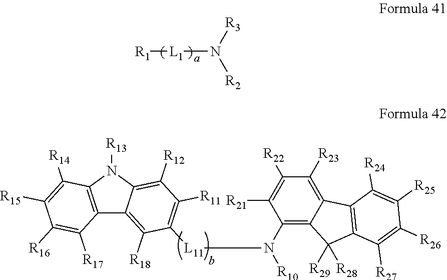
wherein, in Formulae 41 and 42,
R₁₀ is represented by —(Ar₁)ₙ—Ar₂;
R₁₆ is represented by —(Ar₁₁)ₘ—Ar₁₂;
Ar₁, Ar₁₁, L₁, and L₁₁ are each independently a substituted or unsubstituted C₁-C₃₀ alkylene group, a substituted or unsubstituted C₂-C₃₀ alkenylene group, a substituted or unsubstituted C₅-C₃₀ arylene group, a substituted or unsubstituted C₄-C₃₀ heteroarylene group, or —N(Q₁)-;
n, m, a, and b are each independently an integer from 0 to 10;
R₁ through R₃, R₁₁ through R₁₅, R₁₇, R₁₈, R₂₁ through R₂₉, Ar₂, Ar₁₂, and Q₁ are each independently hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₅-C₃₀ aryl group, a C₄-C₃₀ heteroaryl group, or —N(Q₂)(Q₃);
Q₂ and Q₃ are each independently hydrogen, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₅-C₃₀ aryl group, or a substituted or unsubstituted C₄-C₃₀ heteroaryl group; and
n groups of Ar₁ in —(Ar₁)ₙ— are identical to or different from each other, m groups of Ar₁₁ in —(Ar₁₁)ₘ— are identical to or different from each other, a groups of L₁ in -(L₁)ₐ- are identical to or different from each other, and b groups of L₁₁ in -(L₁₁)_{b}- are identical to or different from each other.

10. The organic light-emitting device as claimed in claim 9, wherein Ar₁ and Ar₁₁ are each independently a C₁-C₁₀ alkylene group; a phenylene group; a naphthylene group; an anthrylene group; a fluorenylene group; a carbazolylene group; a pyrazolylene group; a pyridinylene group; a triazinylene group; —N(Q₁)-; or a substituted C₁-C₁₀ alkylene group, a substituted phenylene group, a substituted naphthylene group, a substituted anthrylene group, a substituted fluorenylene group, a substituted carbazolylene group, a substituted pyrazolylene group, a substituted pyridinylene group, or a substituted triazinylene group which have at least one substituent that is a halogen atom, a cyano group, a hydroxyl group, a C₁-C₁₀ alkyl group, a C₁-C₁₀ alkoxy group, a phenyl group, a naphthyl group, or an anthryl group; and
Q₁ is hydrogen; a C₁-C₁₀ alkyl group; a phenyl group; a naphthyl group; a carbazolyl group; a fluorenyl group; or a substituted C₁-C₁₀ alkyl group, a substituted C₁-C₁₀ alkoxy group, a substituted phenyl group, a substituted naphthyl group, a substituted carbazolyl group, or a substituted fluorenyl group which have at least one substituent that is a halogen atom, a cyano group, a hydroxyl group, a C₁-C₁₀ alkyl group, a C₁-C₁₀ alkoxy group, a phenyl group, a naphthyl group, or an anthryl group.

11. The organic light-emitting device as claimed in claim 9, wherein Ar₂ and Ar₁₂ are each independently hydrogen; a C₁-C₁₀ alkyl group; a phenyl group; a naphthyl group; a carbazolyl group; a fluorenyl group; a pyrenyl group; a substituted C₁-C₁₀ alkyl group, a substituted C₁-C₁₀ alkoxy group, a substituted phenyl group, a substituted naphthyl group, a substituted carbazolyl group, a substituted fluorenyl group, or a substituted pyrenyl group which have at least one substituent that is a halogen atom, a cyano group, a hydroxyl group, a C₁-C₁₀ alkyl group, a C₁-C₁₀ alkoxy group, a phenyl group, a naphthyl group, or an anthryl group; or —N(Q₂)(Q₃), wherein Q₂ and Q₃ are each independently hydrogen, a methyl group, an ethyl group, a phenyl group, a methylphenyl group, a biphenyl group, a naphthyl group, or a methylnaphthyl group.

12. The organic light-emitting device as claimed in claim 1, wherein the amount of the cyano group-containing compound in the first layer is about 0.1 to about 20 parts by weight, based on 100 parts by weight of the first layer.

13. The organic light-emitting device as claimed in claim 1, wherein the first layer has a thickness of about 10 Å to about 2,100 Å.

14. The organic light-emitting device as claimed in claim 1, wherein a distance between the first layer and the emission layer is 50 Å or greater.

15. The organic light-emitting device as claimed in claim 1, further comprising, between the first layer and the emission layer, at least one of a hole injection layer and a hole transport layer.

16. The organic light-emitting device as claimed in claim 1, wherein the anthracene-based compound includes at least one of a compound represented by Formula 101 below and a compound represented by Formula 102 below, and the quinolate-based compound includes at least one of lithium quinolate (LiQ) and LiF, 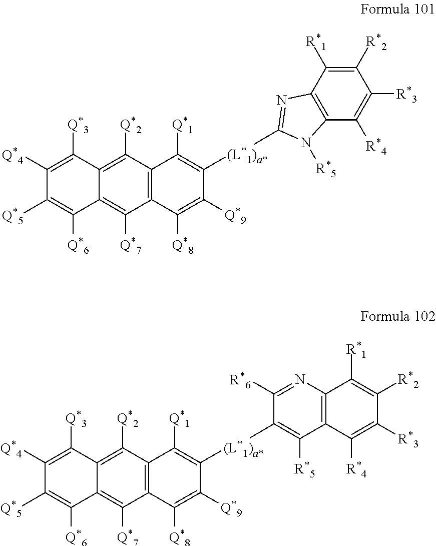
wherein, in Formulae 101 and 102,
R*₁ through R*₆ are each independently a hydrogen atom, a halogen atom, a hydroxy group, a cyano group, a substituted or unsubstituted C₁-C₃₀ alkyl group, a substituted or unsubstituted C₁-C₃₀ alkoxy group, a substituted or unsubstituted C₁-C₃₀ acyl group, a substituted or unsubstituted C₂-C₃₀ alkenyl group, a substituted or unsubstituted C₂-C₃₀ alkynyl group, a substituted or unsubstituted C₆-C₃₀ aryl group, or a substituted or unsubstituted C₃-C₃₀ heteroaryl group, wherein at least two adjacent groups of R*₁ through R*₆ are linked to form a saturated or unsaturated ring;
L*₁ is a single bond, a substituted or unsubstituted C₁-C₃₀ alkylene group, a substituted or unsubstituted C₆-C₃₀ arylene group, or a substituted or unsubstituted C₃-C₃₀ hetero arylene group;
Q*₁ through Q*₉ are each independently a hydrogen atom, a substituted or unsubstituted C₆-C₃₀ aryl group, or a substituted or unsubstituted C₃-C₃₀ heteroaryl group; and
a* is an integer from 1 to 10.

17. The organic light-emitting device as claimed in claim 1, wherein the anthracene-based compound includes at least one of a compound represented by Formula 103 below and a compound represented by Formula 104 below, and the quinolate-based compound includes at least one of lithium quinolate (LiQ) and LiF,

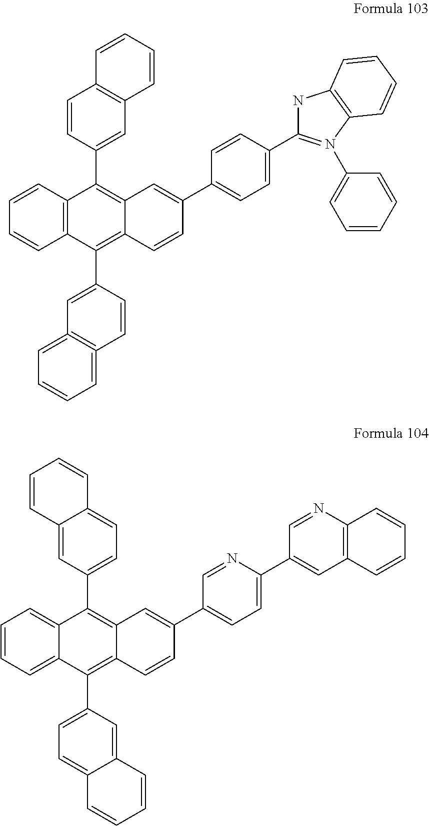

18. The organic light-emitting device as claimed in claim 1, wherein the amount of the anthracene-based compound is about 50 to about 150 parts by weight, based on 100 parts by weight of the quinolate-based compound.

19. The organic light-emitting device as claimed in claim 1, wherein the emission layer includes a blue dopant and a blue host.

20. The organic light-emitting device as claimed in claim 1, wherein the emission layer includes a blue dopant represented by Formula 201 below and a blue host represented by Formula 202 below, 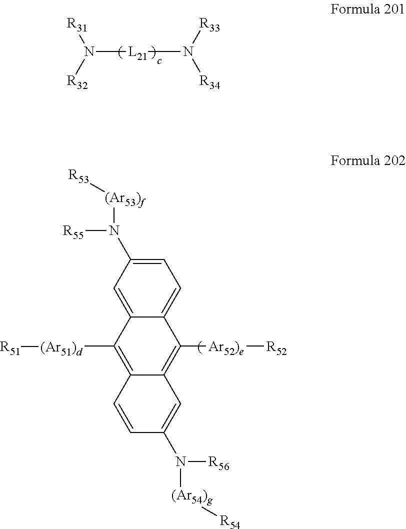
wherein, in Formulae 201 and 202,
L₂₁ is a substituted or unsubstituted C₁-C₃₀ alkylene group, a substituted or unsubstituted C₂-C₃₀ alkenylene group, a substituted or unsubstituted C₅-C₃₀ arylene group, or a substituted or unsubstituted C₄-C₃₀ heteroarylene group;
c is an integer from 1 to 20;
R₃₁ through R₃₄ are each independently a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₅-C₃₀ aryl group, or a substituted or unsubstituted C₄-C₃₀ heteroaryl group.
c groups of L₂₁ in -(L₂₁)_{c}- are identical to or different from each other;
Ar₅₁, A₅₂, Ar₅₃, and Ar₅₄ are each independently a phenylene group, a naphthylene group, an anthrylene group, or a phenyl-substituted anthrylene group,
R₅₁ through R₅₆ are each independently a hydrogen atom, a methyl group, an ethyl group, a propyl group, a butyl group, a phenyl group, a naphthyl group, an anthryl group, a pyrenyl group, a carbazolyl group, or —N(Q₂)(Q₃), wherein Q₂ and Q₃ are each independently a methyl group, a phenyl group, a naphthyl group, or an anthryl group; and
d, e, f, and g are each independently an integer from 0 to 10.
